(19) United States
(12) Patent Application Publication
(10) Pub. No.: US 2026/0150545 A1
(43) Pub. Date: May 28, 2026

(54) DUAL MODE DISPLAY DEVICE AND ELECTRONIC DEVICE INCLUDING THE SAME

(71) Applicant: SAMSUNG DISPLAY CO., LTD., YONGIN-SI (KR)

(72) Inventors: KWANG SOO BAE, Yongin-si (KR); JUNGWOO PARK, Yongin-si (KR); HYANG-A PARK, Yongin-si (KR)

(21) Appl. No.: 19/376,318

(22) Filed: Oct. 31, 2025

(30) Foreign Application Priority Data
Nov. 26, 2024 (KR) 10-2024-0171379
May 12, 2025 (KR) 10-2025-0061204

(51) Int. Cl. H10K 59/35; H10H 29/34; H10H 29/37; H10H 29/80; H10H 29/85; H10H 29/855; H10K 59/122; H10K 59/38; H10K 59/65; H10K 59/80; H10K 59/88; H10K 102/00

(52) U.S. Cl. CPC H10K 59/352; H10H 29/345; H10H 29/37; H10H 29/842; H10H 29/8517; H10H 29/8552; H10K 59/122; H10K 59/38; H10K 59/65; H10K 59/8792; H10K 59/88; H10K 2102/351

(57) ABSTRACT

A display panel includes a first-type pixel, a second-type pixel, and a sensor. to the display panel displays an image using the first-type pixel and the second-type pixel in a first mode, and displays an image using the second-type pixel, without using the first-type pixel, in a second mode. The display panel includes a base layer, a circuit layer disposed on the base layer, and an element layer disposed on the circuit layer, and including a first light emitting element of the first-type pixel, a second light emitting element of the second-type pixel, and a light receiving element of the sensor. The optical path control layer is disposed on the element layer, and includes a first transmission hole corresponding to the second light emitting element, and a second transmission hole corresponding to the light receiving element.

### CROSS-REFERENCE TO RELATED APPLICATIONS

This application claims priority under 35 U.S.C. § 119 to Korean Patent Application No. 10-2024-0171379, filed on Nov. 26, 2024, and Korean Patent Application No. 10-2025-0061204, filed on May 12, 2025, in the Korean Intellectual Property Office, the disclosures of which are incorporated by reference herein in their entireties.

### TECHNICAL FIELD

The present disclosure relates to a display device and, more specifically, to a dual mode display device and an electronic device including the same.

### DISCUSSION OF THE RELATED ART

Multimedia electronic apparatuses, such as televisions, cellular phones, tablet computers, navigation systems, and portable game consoles, may include an electronic apparatus that displays an image. In addition, many vehicles may include an electronic apparatus disposed in an interior thereof for the purpose of displaying vehicle information and providing entertainment.

While in general, many display devices may seek to provide a wide viewing angle so that the viewer may be able to see the display from a variety of different angles, other times it is desired that only a narrow viewing angle be provided so as to provide privacy and to limit display viewing only to one or more people and not to others. For example, it may be required that a driver not be distracted by images on a display screen and so a narrow viewing angle may be used to keep the driver from being distracted while a passenger views displayed images on the display screen.

### SUMMARY

Embodiments of the present disclosure provide a display device capable of switching between a wide viewing angle mode and a narrow viewing angle mode and improving sensing performance, and an electronic apparatus including the same.

A display device includes a display panel, an optical path control layer disposed on the display panel, and a panel driver operating the display panel in a first mode or a second mode. The display panel includes a first-type pixel, a second-type pixel, and a sensor, displays an image using the first-type pixel and the second-type pixel in a first mode, and displays an image using the second-type pixel, and not the first-type pixel in a second mode.

The display panel includes a base layer, a circuit layer disposed on the base layer, and an element layer disposed on the circuit layer, and including a first light emitting element of the first-type pixel, a second light emitting element of the second-type pixel, and a light receiving element of the sensor. The optical path control layer is disposed on the element layer, and includes a first transmission hole corresponding to the second light emitting element, and a second transmission hole corresponding to the light receiving element.

An electronic apparatus includes a display panel, an optical path control layer disposed on the display panel, a panel driver operating the display panel in a first mode or a second mode, and a processor configured to provide an image signal to the panel driver. The display panel includes a first-type pixel, a second-type pixel, and a sensor, displays an image using the first-type pixel and the second-type pixel in a first mode, and displays an image using the second-type pixel, and not the first-type pixel in a second mode.

The display panel includes a base layer, a circuit layer disposed on the base layer, and an element layer disposed on the circuit layer, and including a first light emitting element of the first-type pixel, a second light emitting element of the second-type pixel, and a light receiving element of the sensor. The optical path control layer is disposed on the element layer, and includes a first transmission hole corresponding to the second light emitting element, and a second transmission hole corresponding to the light receiving element.

### BRIEF DESCRIPTION OF THE FIGURES

The above and other objects and features of the present disclosure will become apparent by describing in detail embodiments thereof with reference to the accompanying drawings.

FIG. 1A is a plan view of a display device according to an embodiment of the present disclosure.

FIG. 1B is a perspective view of a display device according to an embodiment of the present disclosure.

FIG. 2 is a perspective view illustrating an interior of a vehicle including a display device disposed therein, according to an embodiment of the present disclosure.

FIG. 3A is a perspective view illustrating a second display region of a display device, according to an embodiment of the present disclosure, operating in a first mode.

FIG. 3B is a perspective view illustrating a second display region of a display device, according to an embodiment of the present disclosure, operating in a second mode.

FIG. 4A is a perspective view illustrating a first display region of a display device, according to an embodiment of the present disclosure, operating in a first mode.

FIG. 4B is a perspective view illustrating a first display region of a display device, according to an embodiment of the present disclosure, operating in a second mode.

FIG. 5 is a cross-sectional view of a display device according to an embodiment of the present disclosure.

FIG. 6 is a block diagram of a display device according to an embodiment of the present disclosure.

FIG. 7A is a circuit diagram illustrating a pixel and a sensor according to an embodiment of the present disclosure.

FIG. 7B is a timing diagram illustrating a waveform to describe operations of a pixel and a sensor illustrated in FIG. 7A.

FIG. 8A is a plan view illustrating a display panel operating in a first mode according to an embodiment of the present disclosure.

FIG. 8B is a plan view illustrating a display panel operating in a second mode according to an embodiment of the present disclosure.

FIG. 9A is a cross-sectional view illustrating a (2-2)-th light emitting element, a (2-4)-th light emitting element, and a second light receiving element, according to an embodiment of the present disclosure.

FIG. 9B is a cross-sectional view illustrating a (1-2)-th light emitting element, a (1-4)-th light emitting element, and a first light receiving element according to an embodiment of the present disclosure.

FIG. 9C is a cross-sectional view illustrating a (1-2)-th light emitting element, a (1-4)-th light emitting element, and a first light receiving element, according to an embodiment of the present disclosure.

FIG. 10A is a plan view illustrating a display panel operating in a first mode, according to an embodiment of the present disclosure.

FIG. 10B is a plan view illustrating a display panel operating in a second mode, according to an embodiment of the present disclosure.

FIG. 11A is a cross-sectional view illustrating a (1-4)-th light emitting element, a (2-2)-th light emitting element, and a second light receiving element according to an embodiment of the present disclosure.

FIG. 11B is a view illustrating the range of an image capturing region adjusted by first and second light blocking layers illustrated in FIG. 11A.

FIG. 12 is a graph illustrating a signal-to-noise ratio as a function of a thickness of a window.

FIG. 13 is a block diagram of an electronic apparatus according to an embodiment of the present disclosure.

FIG. 14 illustrates schematic views of electronic apparatuses according to various embodiments.

### DETAILED DESCRIPTION

In the specification, the expression that a first component (or region, layer, or part) is “on”, “connected to”, or “coupled to” a second component refers to that the first component is directly on, connected to, or coupled to the second component or refers to that a third component is interposed therebetween.

The same reference numeral may be assigned to the same component throughout the drawings and the specification. While each drawing may represent one or more particular embodiments of the present disclosure, drawn to scale, such that the relative lengths, thicknesses, proportions, dimensions, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. The term “and/or” includes any and all combinations of one or more of associated components.

Although the terms “first”, or “second” may be used to describe various components, the components should not necessarily be construed as being limited by the terms. The terms are used to distinguish one component, part, region, layer, or portion from another component, part, region, layer, or portion. For example, without departing from the scope and spirit of the present disclosure, a first component, a first part, a first region, a first layer, or a first portion may be referred to as a second component, a second part, a second region, a second layer, or a second portion, and similarly, the second component, the second part, the second region, the second layer, or the second portion may be referred to as the first component, the first part, the first layer, or the first portion. The singular forms are intended to include the plural forms unless the context clearly indicates otherwise.

In addition, the terms “under”, “at a lower portion”, “above”, “an upper portion” are used to describe the relationship between components illustrated in drawings. The terms are relative and will be described with reference to a direction indicated in the drawing.

It will be further understood that the terms “comprise,” “include,” or “including,” or “have” or “having” specify the presence of stated features, numbers, steps, operations, components, parts, or the combination thereof, but do not preclude the presence or addition of one or more other features, numbers, steps, operations, components, components, and/or the combination thereof.

Embodiments of the present disclosure relate to a display device that dynamically switches between two viewing modes: (1) a wide viewing angle mode for general use, and (2) a narrow viewing angle mode for privacy protection. This dual-mode functionality is achieved through a sophisticated arrangement of different pixel types and integrated sensors within the display panel. For example, the panel may incorporate first-type (e.g., wide-angle) pixels and second-type (e.g., narrow-angle) pixels, along with optical sensors capable of biometric recognition, such as fingerprint detection. In the wide-angle mode, both pixel types may contribute to the image output, allowing for broad visibility. In the narrow-angle mode, only the second-type pixels operate, and their light output may be restricted through an optical path control layer, reducing visibility from off-angles and thus protecting user privacy.

A light blocking layer (referred to as a black matrix or BM) may be integrated into the optical path control layer. This layer may be selectively patterned to include ring-shaped blocking structures exclusively over the second-type pixels and the optical sensors. Transmission holes may be precisely aligned with the second-type light-emitting elements and the light-receiving elements of the sensors. This architecture may ensure that the viewing angle is narrowed exclusively when the second-type pixels are active, while simultaneously enhancing the performance of the sensors by controlling the capture range of light reaching them. As a result, even if the thickness of the window layer above the display increases, the optical path remains optimized, and the sensors retain high fidelity.

In terms of construction, the display may include multiple layers including a base substrate, a circuit layer, and an element layer containing both light-emitting and light-receiving elements. Above this is the input sensing layer (e.g., for touch input) and the optical path control layer, followed by a window layer. The driving circuit may enable precise mode switching depending on contextual factors, such as user preferences or environmental conditions (e.g., switching to the narrow viewing angle when sensitive content is displayed or when a vehicle exceeds a certain speed to prevent distractions). Through these embodiments, the invention enables high-resolution display performance, integrated sensing functionality, and enhanced privacy protection, all within a single compact and efficient display module.

According to embodiments of the present disclosure, within a single image of a display device, a portion of the image may be displayed with the wide viewing angle while another portion of the same image may be displayed with the narrow viewing angle so that where the displayed image includes sensitive components and general components, the sensitive components may be displayed with the narrow viewing angle while the general components are displayed with the wide viewing angle.

Hereinafter, embodiments of the present disclosure will be described with reference to drawings.

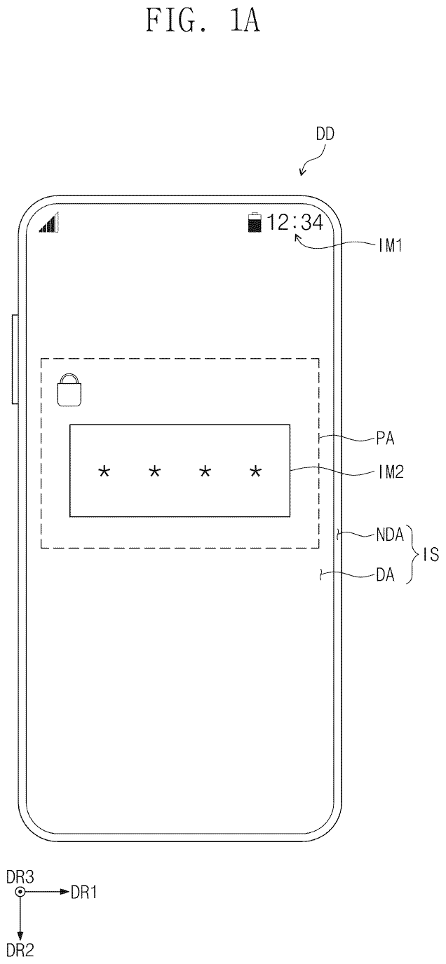

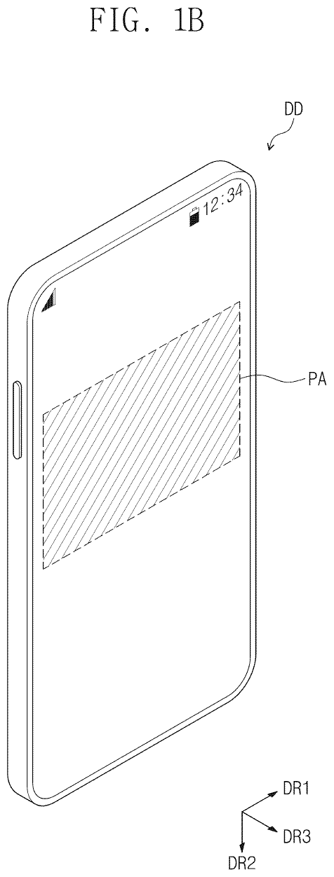

FIG. 1A is a plan view of a display device, according to an embodiment of the present disclosure, and FIG. 1B is a perspective view of a display device, according to an embodiment of the present disclosure.

Referring to FIGS. 1A and 1B, a display device DD may be activated in response to an electrical signal. The display device DD may be a cellular phone, a tablet computer, a smartwatch, a laptop/desktop computer, a computer monitor, or a smart television (TV).

The display device DD may display images IM1 and IM2 on a display surface IS which is in a plane defined by a first direction DR1 and a second direction DR2 intersecting the first direction DR1. The display surface IS may correspond to a front surface of the display device DD. The images IM1 and IM2 may include static images as well as moving images. A normal direction of the display surface IS, that is, a thickness direction of the display device DD, may be indicated by a third direction DR3. A front surface (or a top surface) and a back surface (or a bottom surface), which is described below, of each layer or unit are distinguished in the third direction DR3.

The display surface IS of the display device DD may be classified into a display region DA and a non-display region NDA. The display region DA may be a region for displaying the images IM1 and IM2. A user may recognize the images IM1 and IM2 through the display region DA. According to an embodiment, the display region DA is illustrated as a rectangular shape having rounded vertices. However, this is provided for the illustrative purpose, and the display region DA may have various other shapes. Accordingly, the display region DA is not necessarily limited to any one embodiment.

The non-display region NDA may be adjacent to the display region DA. The non-display region NDA may have a specific color. The non-display region NDA may surround the display region DA on at least two sides thereof. Accordingly, the shape of the display region DA may be substantially defined by the non-display region NDA. However, this is provided for illustrative purposes. The non-display region NDA may be disposed adjacent only to one side of the display region DA, or may be omitted. The display device DD, according to an embodiment of the present disclosure, may include various embodiments and is not necessarily limited to any one embodiment.

The display device DD may operate in the first mode or the second mode. The first mode may be a general mode, a public mode, or a wide viewing angle mode in which a screen is displayed at a first viewing angle. The second mode may be a viewing angle control mode for displaying a screen at a second viewing angle that is narrower than the first viewing angle. The second mode may be referred to as a private mode, a privacy protection mode, or a narrow viewing angle mode. The first viewing angle and the second viewing angle may be defined as angles allowing viewing without the distortion of the image based on a normal direction of the display surface IS.

The images IM1 and IM2 may include the first image IM1 and the second image IM2. The first image IM1 may be an image displayed on one region operating in the first mode. The second image IM2 may be an image illustrated on a privacy protection region PA operating in the second mode.

Referring to FIGS. 1A and 1B, the first image IM1 is illustrated as an image representing a state such as a state of capacity (SOC) of a battery or a current time, and the second image IM2 is displayed as an image requiring privacy protection such as a blank for entering a password. However, this is provided for illustrative purposes. The configurations of the first image IM1 and the second image IM2, according to an embodiment of the present disclosure, are not necessarily limited thereto. Alternatively, an entire portion of the display region DA may be defined as the privacy protection region PA.

When the display device DD is viewed from the front, for example, in a direction parallel to the normal direction or the third direction DR3, in the first mode or the second mode, the first image IM1 and the second image IM2 generated by the display device DD may be viewed by a user.

When the display device DD is viewed at an angle beyond the second viewing angle in the second mode, the second image IM2 might not be viewed. For reference, when the display device DD is viewed at an angle beyond the second viewing angle in the first mode, the user may view the second image IM2.

The second viewing angle in the second mode may be variously set and the luminance at the second viewing angle may be variously set. For example, the second viewing angle may be 45 degrees, and the luminance at 45 degrees may be 10 % of the maximum luminance. However, the present disclosure is not necessarily limited thereto.

The display device DD may selectively operate in one of the first mode for displaying a screen at the first viewing angle and the second mode for displaying the screen at the second viewing angle that is narrower than the first viewing angle. Switching between the first mode and the second mode may be controlled by a user or the switching from the first mode to the second mode may be made, when a specific application is executed. For example, when an application having a risk of exposing personal information, such as a banking application or a memo application, is executed, the display device DD may be switched from the first mode to the second mode.

Thus, the display device may operate in two viewing modes: a wide-angle first mode for general visibility and a narrow-angle second mode for privacy protection. It features a display surface divided into a display region for showing images and a non-display region that may border or define its shape, with general content such as time or battery shown in public mode and sensitive content like passwords restricted in private mode. The device can automatically switch to privacy mode based on context, such as launching certain applications, limiting visibility of specific content when viewed from oblique angles.

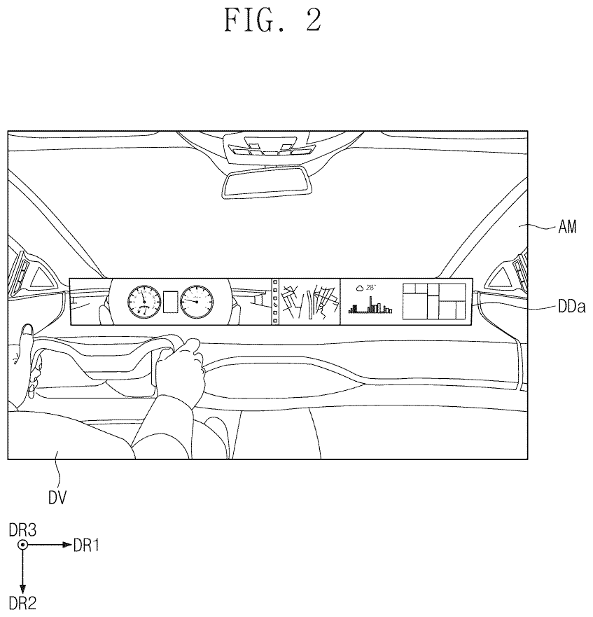

FIG. 2 is a perspective view illustrating an interior of a vehicle including a display device disposed in the vehicle according to an embodiment of the present disclosure.

Referring to FIG. 2, a display device DDa may be disposed inside a vehicle AM. The display device DDa may be disposed inside the vehicle AM to provide various pieces of information to a driver DV (or a user). The display device DDa may provide images such as weather, speed, a map, or a movie to the driver DV. The display device DDa may be a touch-based electronic apparatus operable depending on a touch input of the driver DV.

Although FIG. 2 illustrates the vehicle display device DDa, an embodiment of the present disclosure is not necessarily limited thereto. For example, the display device DDa, according to an embodiment of the present disclosure, may be used in an electronic apparatus such as a smartphone, a digital camera, a laptop/notebook computer, a computer monitor, and a smart television which provide images to a user.

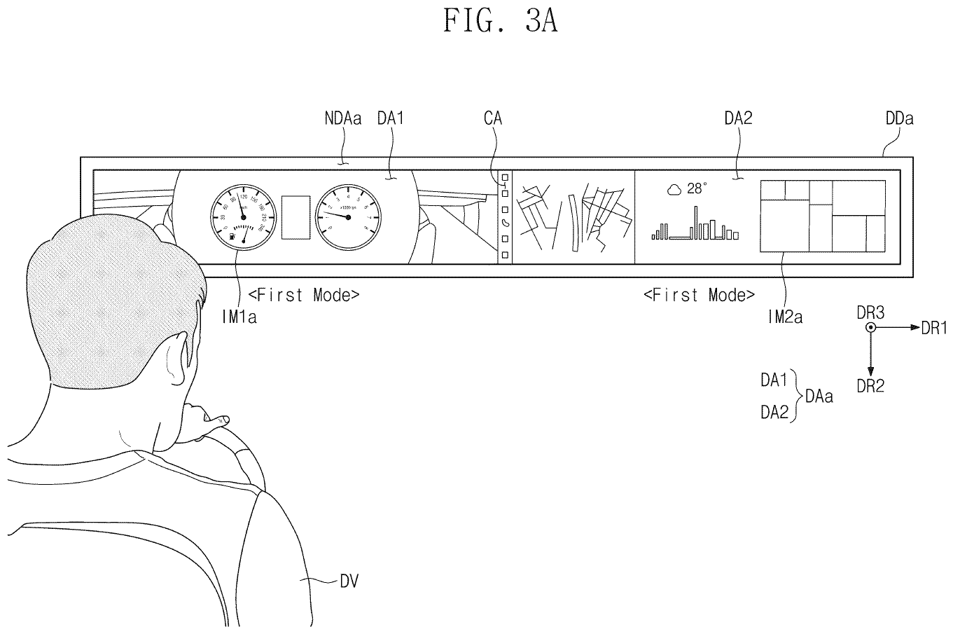

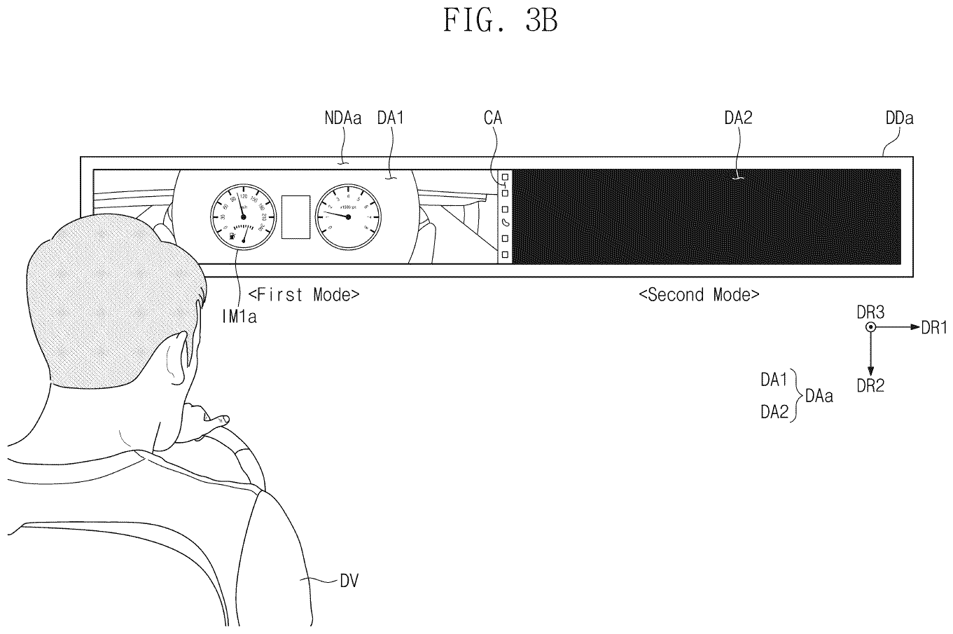

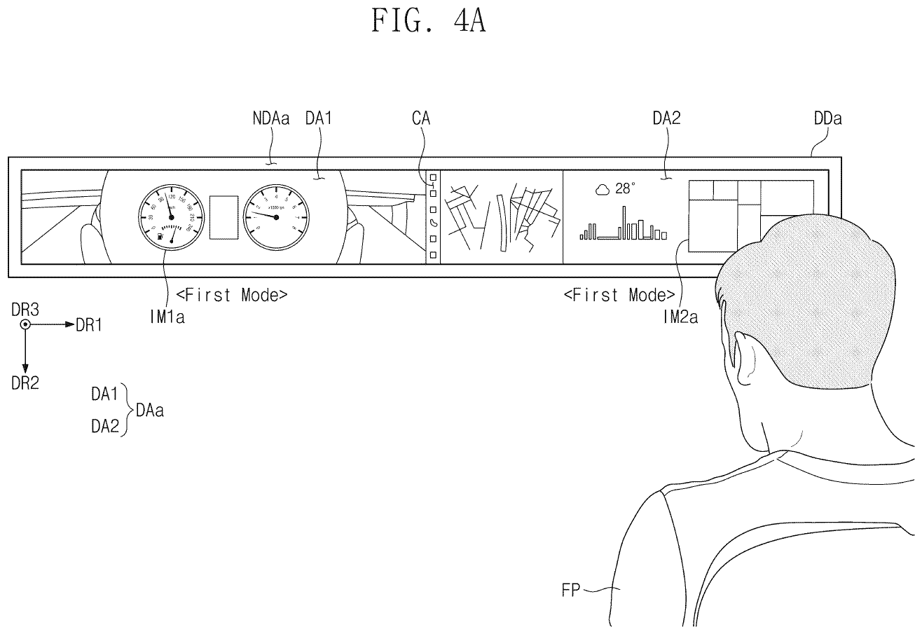

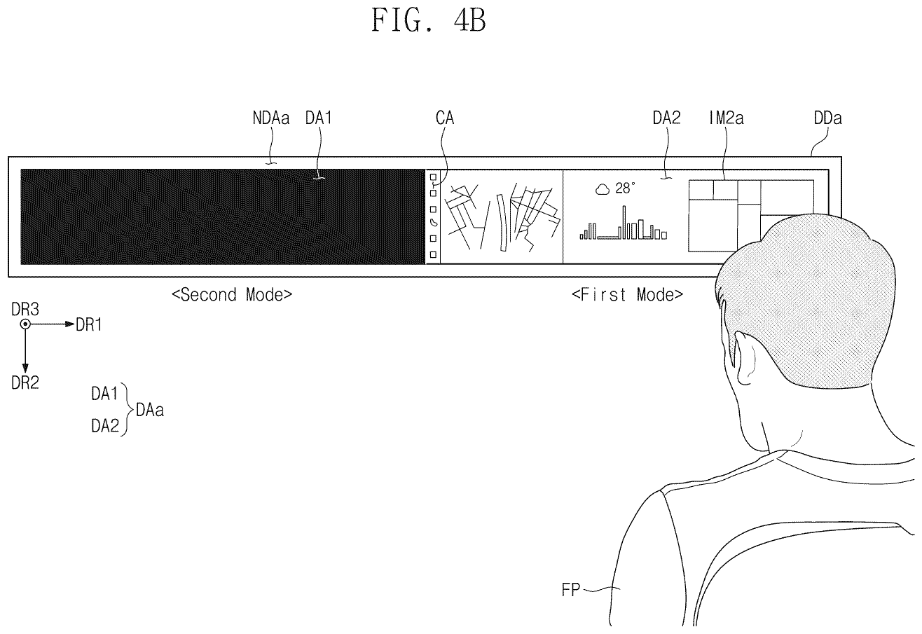

FIG. 3A is a perspective view illustrating a second display region of the display device, according to an embodiment of the present disclosure, operating in the first mode, and FIG. 3B is a perspective view illustrating a second display region of a display device, according to an embodiment of the present disclosure, operating in the second mode. FIG. 4A is a view illustrating a first display region of a display device, according to an embodiment of the present disclosure, operating in the first mode, and FIG. 4B is a perspective view illustrating a first display region of a display device, according to an embodiment of the present disclosure, operating in the second mode.

Referring to FIGS. 3A and 3B, the display device DDa may have a plane defined by the first direction DR1 and the second direction DR2 crossing each other. The display device DDa may have a pair of longer sides extending in the first direction DR1 and a pair of shorter sides extending in the second direction DR2. The display device DDa may have a substantially rectangular shape, but the shape of the display device DDa is not necessarily limited thereto and may have various shapes. In addition, corner portions of the display device DDa, which connects long sides to short sides, may have a curved shape.

A front surface of the display device DDa may be defined as a display surface and may have a plane defined by the first direction DR1 and the second direction DR2. Images generated by the display device DDa may be provided to a user through the display surface.

The display device DDa may include a display region DAa and a non-display region NDAa proximate to the display region DAa. The display region DAa displays an image, and the non-display region NDAa might not display an image. The non-display region NDAa may surround the display region DAa on at least two sides thereof and may define a border, which has a specific color, of the display device DDa.

According to an embodiment of the present disclosure, the display region DAa may include a first display region DA1 and a second display region DA2. The first display region DA1 and the second display region DA2 may be adjacent to each other in the first direction DR1, and an intermediate region CA may be interposed between the first display region DA1 and the second display region DA2. A first-side image IM1a is displayed on the first display region DA1, and a second-side image IM2a is displayed on the second display region DA2. The first display region DA1 may be a region in front of a driver seat of the vehicle AM (see FIG. 2), and the second display region DA2 may be a region in front of a passenger seat of the vehicle AM.

According to an embodiment of the present disclosure, the first display region DA1 and the second display region DA2 may be driven independently from each other. For example, the first display region DA1 may display an image in the first mode or the second mode, and the second display region DA2 may also display an image in the first mode or the second mode. The first mode may be a general mode or a public mode for displaying a screen at a first viewing angle, and the second mode may be a viewing angle control mode for displaying the screen at the second viewing angle that is narrower than the first viewing angle. The second mode may be referred to as a private mode or a privacy protection mode. When any one of the first and second display regions DA1 and DA2 operates in the second mode, a viewing range of an image becomes narrow, such that the image may be substantially viewed only from a front direction. In contrast, when any one of the first and second display regions DA1 and DA2 operates in the first mode, the viewing range of the image becomes wide, such that the image is viewed even from a lateral direction.

As illustrated in FIGS. 3A and 4A, both the first and second display regions DA1 and DA2 may operate in the first mode. In the first mode, the driver DV of the vehicle AM may recognize not only the first-side image IM1a displayed on the first display region DA1 but also the second-side image IM2a displayed on the second display region DA2. In addition, in the first mode, a passenger FP at a passenger seat may view not only the second-side image IM2a displayed on the second display region DA2, but also the first-side image IM1a displayed on the first display region DA1.

However, as illustrated in FIG. 3B, the first display region DA1 may operate in the first mode, and the second display region DA2 may operate in the second mode. In this case, the driver DV may view the first-side image IM1a displayed on the first display region DA1 but might not view the second-side image IM2a displayed on the second display region DA2.

According to an embodiment of the present disclosure, a mode switching (for example, switching from the first mode to the second mode or from the second mode to the first mode) of the second display region DA2 may be automatically performed based on a traveling speed of the vehicle AM. For example, when the traveling speed of the vehicle AM is at most a preset reference speed, the second display region DA2 may display an image in the first mode. However, when the traveling speed of the vehicle AM exceeds the preset reference speed, the mode of the second display region DA2 may be switched to the second mode. Accordingly, when the traveling speed exceeds the reference speed, the driver DV might not view the second-side image IM2a displayed on the second display region DA2.

In contrast, as illustrated in FIG. 4B, the first display region DA1 may operate in the second mode, and the second display region DA2 may operate in the first mode. In this case, the passenger FP at the passenger seat may view the second-side image IM2a displayed on the second display region DA2 but might not view the first-side image IM1a displayed on the first display region DA1.

According to an embodiment of the present disclosure, a mode switching manner between the first and second display regions DA1 and DA2 may be performed in various ways depending on operations (or settings) by the user.

Thus, the display device may be installed in a vehicle and can present general information such as maps, speed, or media to both the driver and passenger. It features two independently controlled display regions, one in front of the driver and one in front of the passenger, that can each operate in either a wide viewing angle mode or a narrow privacy mode. Depending on user settings or the vehicle's speed, the display regions can switch modes, allowing selective visibility of information to improve safety and privacy, such as hiding passenger content from the driver at high speeds.

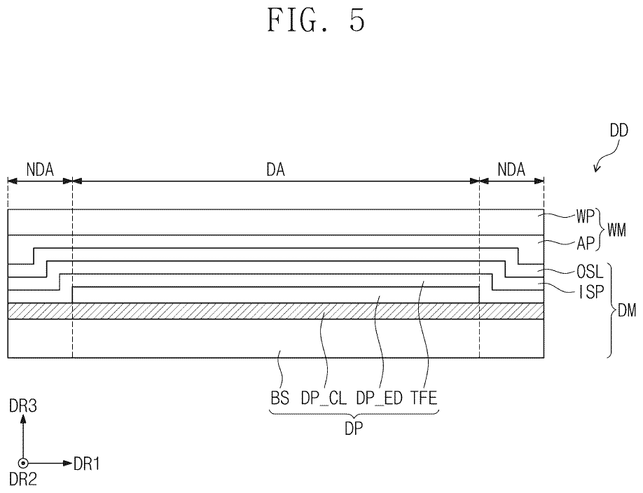

FIG. 5 is a cross-sectional view of a display device according to an embodiment of the present disclosure.

Referring to FIG. 5, the display device DD may include a display module DM and a window assembly WM disposed on the display module DM. The display module DM may include a display panel DP, an input sensing layer ISP disposed on the display panel DP, and an optical path control layer OSL disposed on the input sensing layer ISP.

The display panel DP may be an emissive-type display panel and, for example, may be an organic light emitting display panel, an inorganic light emitting display panel, a quantum dot display panel, a micro LED display panel, or a nano LED display panel. The display panel DP may be referred to as a display layer. The display panel DP may include a base layer BS, a circuit layer DP_CL, an element layer DP_ED, and an encapsulating layer TFE.

The base layer BS may provide a base surface for disposing the circuit layer DP_CL. The base layer BS may be a rigid substrate or a flexible substrate which allows bending, folding, or rolling to at least a noticeable extent without cracking or otherwise sustaining damage thereto. The base layer BS may be a glass substrate, a metal substrate, or a polymer substrate. However, the embodiment is not necessarily limited thereto, and the base layer BS may be an inorganic base layer, an organic base layer, or a composite material layer.

The circuit layer DP_CL may be disposed on the base layer BS. The circuit layer DP_CL may include a plurality of insulating layers, a plurality of conductive layers, and a semiconductor layer. The plurality of conductive layers of the circuit layer DP_CL may form signal lines or a pixel driving circuit.

The element layer DP_ED may be disposed on the circuit layer DP_CL. The element layer DP_ED may include light emitting elements. For example, the element layer DP_ED may include an organic light emitting diode, an inorganic light emitting diode, a quantum dot, a quantum rod, a micro LED, or a nano LED.

The encapsulating layer TFE may be disposed on the element layer DP_ED. The encapsulating layer TFE may protect the element layer DP_ED from foreign substances such as moisture, oxygen, and dust particles.

The input sensing layer ISP may be disposed on the encapsulating layer TFE. The input sensing layer ISP may detect an external input, convert the input into a specific input signal, and provide the input signal to the display panel DP. For example, according to an embodiment, the input sensing layer ISP in a display device DD may be a touch sensing unit which detects a touch. The input sensing layer ISP may sense a direct touch by a user, an indirect touch by a user, a direct touch by an object, or an indirect touch by an object.

The input sensing layer ISP may sense any one of a position of and a strength (pressure) of the touch applied from the outside. The display panel DP may receive an input signal from the input sensing layer ISP, and may generate an image corresponding to the input signal. For example, the input sensing layer ISP may sense an external input using a capacitive manner. However, this is provided for illustrative purposes. The driving manner of the input sensing layer ISP is not necessarily limited to any one embodiment.

The display panel DP and the input sensing layer ISP may be formed through subsequent processes. For example, the input sensing layer ISP may be directly formed on the encapsulating layer TFE. An adhesive might not be interposed between the input sensing layer ISP and the display panel DP. Alternatively, the input sensing layer ISP may be bonded to the display panel DP through an adhesive. The adhesive may include a conventional adhesive or adhesion.

In this specification, any first component directly disposed/formed on a second component may indicate that a third component is not interposed between the first and second components. For example, any first component “directly disposed/formed” on a second component may indicate that the first component makes “contact” with the second component.

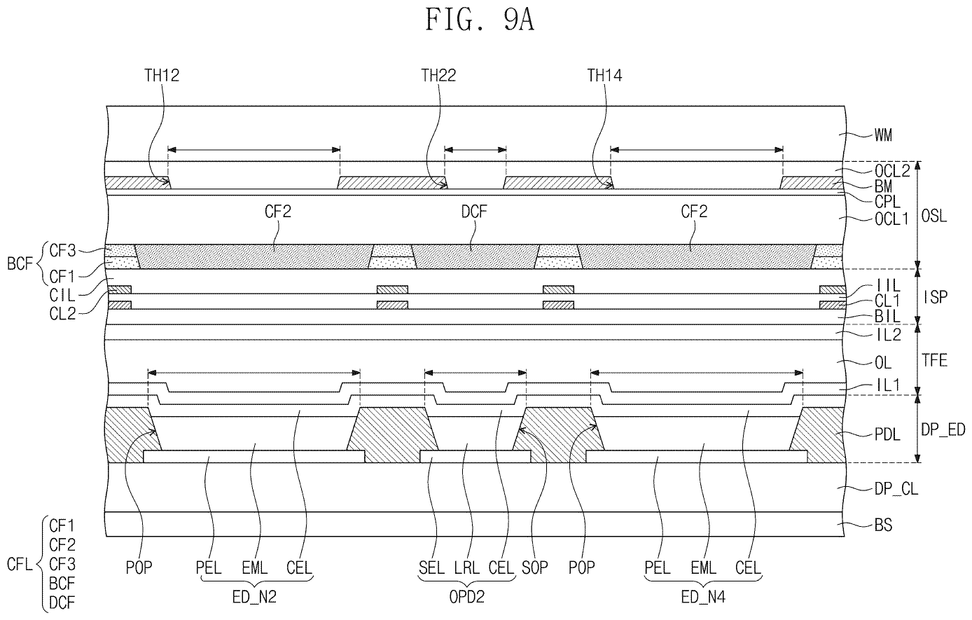

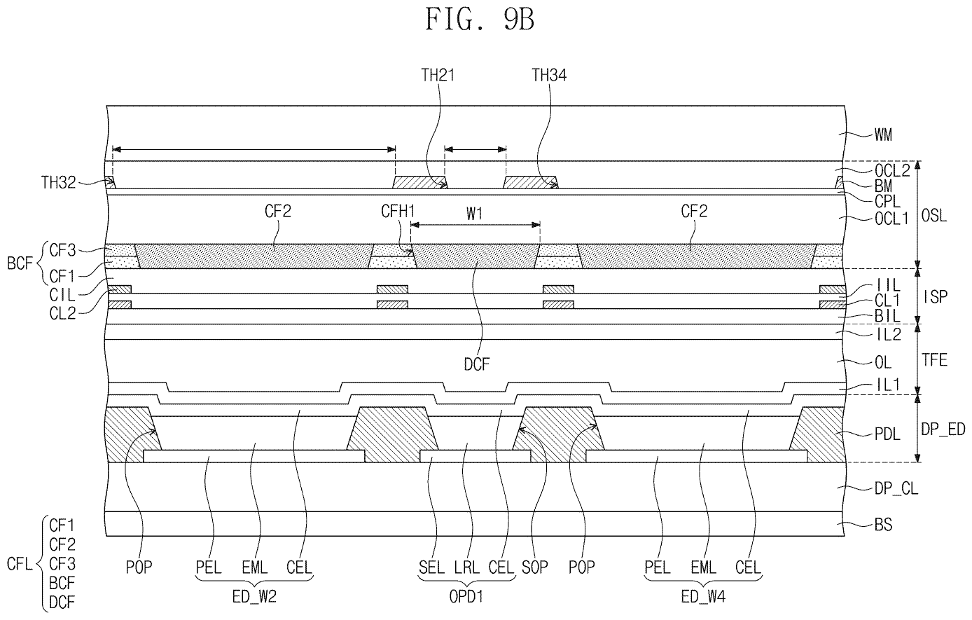

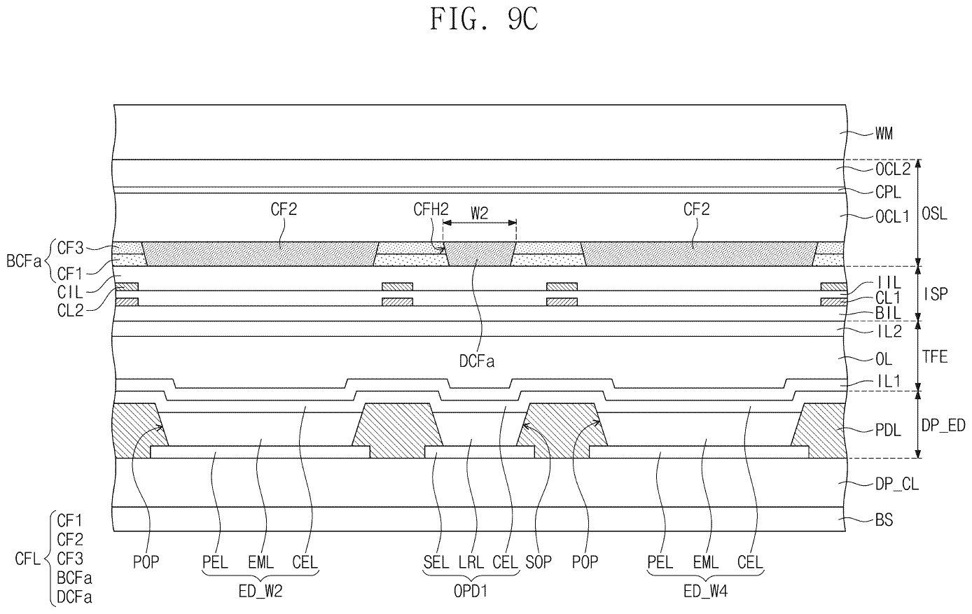

The optical path control layer OSL may be disposed on the input sensing layer ISP. The optical path control layer OSL may include a structure to control a path of light emitted from the display panel DP. The optical path control layer OSL may be formed through a process subsequent to processes for the display panel DP and the input sensing layer ISP, and may be directly disposed on the input sensing layer ISP. However, the present disclosure is not necessarily limited thereto. For example, the optical path control layer OSL may be bonded to the input sensing layer ISP through an adhesive layer. A configuration of the optical path control layer OSL will be specifically described below with reference to FIGS. 9A to 9C.

The window assembly WM may be disposed on the display module DM. The window assembly WM may include a window WP and an adhesive layer AP. The window assembly WM may further include at least one functional layer disposed on the window WP. For example, the functional layer may be a hard coating layer or a fingerprint-resistant coating layer, but an embodiment is not necessarily limited thereto.

The window WP may include an optically transparent insulating material. The window WP may be a glass substrate or a polymer substrate. For example, the window WP may be a tempered glass substrate subjected to reinforcement treatment. The adhesive layer AP may be interposed between the display module DM and the window WP. A component (for example, the display module DM or the optical path control layer OSL) adjacent to the window WP may be bonded to the window WP by the adhesive layer AP. The adhesive layer AP may include conventional adhesives such as a pressure sensitive adhesive (PSA), an optically clear adhesive (OCA), or an optical clear resin (OCR), and is not necessarily limited to any one embodiment. Alternatively, the adhesive layer AP may be omitted.

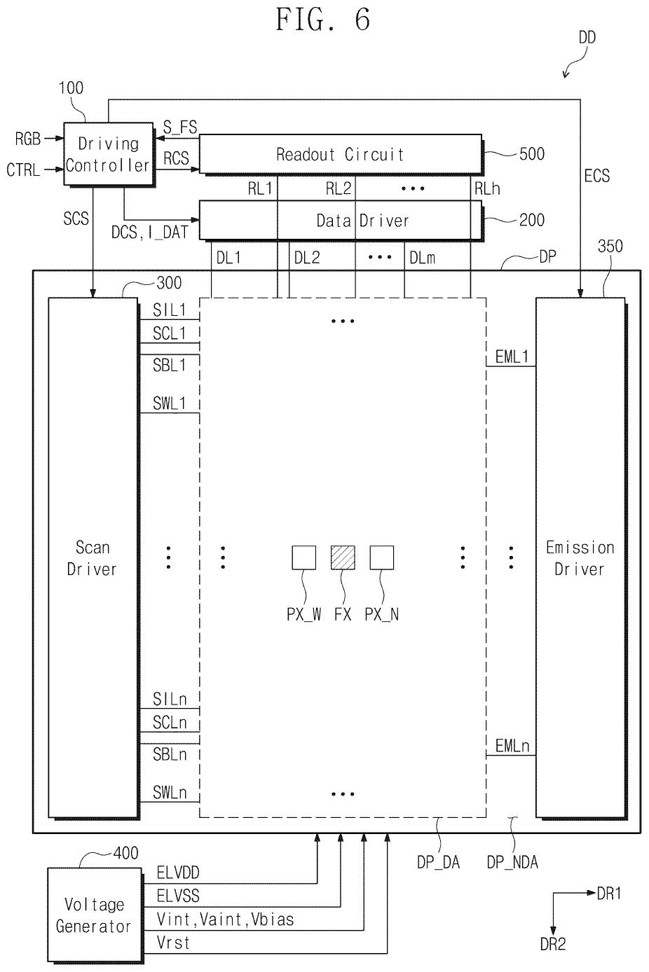

FIG. 6 is a block diagram of a display device according to an embodiment of the present disclosure.

Referring to FIG. 6, the display device DD includes the display panel DP and a panel driver. According to an embodiment of the present disclosure, the panel driver includes a driving controller 100, a data driver 200, a scan driver 300, an emission driver 350, a voltage generator 400, and a readout circuit 500. The panel driver may drive the display panel DP in the first mode or the second mode, in response to the first mode enable signal or the second mode enable signal received from a processor.

The driving controller 100 receives an image signal RGB and a control signal CTRL from a processor. The driving controller 100 generates image data I_DAT obtained by converting a data format of the image signal RGB to match an interface specification with the data driver 200. The driving controller 100 outputs a first control signal SCS, a second control signal ECS, a third control signal DCS, and a fourth control signal RCS. The first mode enable signal and the second mode enable signal may be signals included in the control signal CTRL.

The data driver 200 receives the third control signal DCS and the image data I_DAT from the driving controller 100. The data driver 200 converts the image data I_DAT into data signals and outputs the data signals to the plurality of data lines DL1 to DLm, which are to be described below. The data signals are analog voltages corresponding to the grayscale values of the image data I_DAT.

The scan driver 300 receives the first control signal SCS from the driving controller 100. The scan driver 300 may output scan signals to the scan lines in response to the first control signal SCS.

The voltage generator 400 generates voltages necessary for an operation of the display panel DP. According to an embodiment, the voltage generator 400 generates a first driving voltage ELVDD, a second driving voltage ELVSS, a first initializing voltage Vint, a second initializing voltage Vaint, a bias voltage Vbias, and a reset voltage Vrst.

The display panel DP includes a display region DP_DA and a non-display region DP_NDA adjacent to the display region DP_DA. The display region DP_DA corresponds to the display region DA illustrated in FIG. 1A, and the non-display region DP_NDA may correspond to the non-display region NDA illustrated in FIG. 1A. The display region DP_DA is a region for actually displaying an image, and the non-display region DP_NDA is a bezel region in which an image is not displayed.

The display panel DP may include a plurality of pixels PX_W and PX_N disposed in the display region DP_DA and a plurality of sensors FX disposed in the display region DP_DA. According to an embodiment of the present disclosure, each of the plurality of sensors FX may be disposed between two pixels PX_W and PX_N adjacent to each other. The plurality of pixels PX_W and PX_N and the plurality of sensors FX may be alternately disposed in the first direction DR1 and the second direction DR2. However, the present disclosure is not necessarily limited thereto. For example, at least two pixels PX_W and PX_N may be disposed between two sensors FX, which are adjacent to each other, among the plurality of sensors FX in first direction DR1, or may be disposed between two sensors FX, which are adjacent to each other, in the second direction DR2.

The sensors FX may be sensors to recognize external information. In this case, the external information may be biometrics information. According to an embodiment of the present disclosure, the sensors may be a fingerprint recognizing sensor, a proximity sensor, an iris recognizing sensor, a blood pressure measurement sensor, or an illuminance sensor. In addition, the sensors FX may be optical sensors which recognize biometric information through an optical manner.

The display panel DP further includes initializing scan lines SIL1 to SILn, compensating scan lines SCL1 to SCLn, write scan lines SWL1 to SWLn, black scan lines SBL1 to SBLn, emission control lines EML1 to EMLn, data lines DL1 and DL2 to DLm, and readout lines RL1 and RL2 to RLh. The initializing scan lines SIL1 to SILn, the compensating scan lines SCL1 to SCLn, the write scan lines SWL1 to SWLn, the black scan lines SBL1 to SBLn, and an emission control lines EML1 to EMLn extend in the first direction DR1. The initializing scan lines SIL1 to SILn, the compensating scan lines SCL1 to SCLn, the write scan lines SWL1 to SWLn, the black scan lines SBL1 to SBLn, and the emission control lines EML1 to EMLn are spaced apart from each other in the second direction DR2. The data lines DL1 to DLm and the readout lines RL1 to RLh extend in the second direction DR2 and are spaced apart from each other in the first direction DR1. In this case, ‘n’, ‘m’, and ‘h’ are integers equal to or greater than 1.

The plurality of pixels PX_W and PX_N are electrically connected to the initializing scan lines SIL1 to SILn, the compensating scan lines SCL1 to SCLn, the write scan lines SWL1 to SWLn, the black scan lines SBL1 to SBLn, the emission control lines EML1 to EMLn, and the data lines DL1 to DLm, respectively. For example, each of the plurality of pixels PX_W and PX_N may be electrically connected to four scan lines. However, the number of scan lines connected to each pixel PX_W and PX_N is not necessarily limited thereto and may be varied.

The plurality of sensors FX are electrically connected to the write scan lines SWL1 to SWLn and the readout lines RL1 to RLh, respectively. Each of the plurality of sensors FX may be electrically connected to one scan line. However, the present disclosure is not necessarily limited thereto. The number of scan lines connected to each sensor FX may be variable. According to an embodiment of the present disclosure, the number of readout lines RL1 to RLh may be less than or equal to the number of data lines DL1 to DLm. For example, the number of readout lines RL1 to RLh may correspond to ½, ¼, or ⅛ of the number of data lines DL1 to DLm.

The plurality of pixels PX_W and PX_N may include wide pixels PX_W, which may be referred to as normal pixels or first-type pixels, and narrow pixels PX_N, which may be referred to as private pixels or second-type pixels. The wide pixels PX_W and the narrow pixels PX_N may be alternately arranged in the first direction DR1 or the second direction DR2. The wide pixels PX_W and the narrow pixels PX_N may be substantially the same configuration. However, a structure (or referred to as a black matrix) to control a viewing angle may be additionally disposed over the narrow pixels PX_N.

The display panel DP displays an image at the first viewing angle using the wide pixels PX_W and the narrow pixels PX_N, in the first mode and displays an image at the second viewing angle that is narrower than the first viewing angle only using the narrow pixels PX_N, in the second mode. An emission range of light output from the narrow pixels PX_N is narrowed through the optical path control layer OSL (see FIG. 5). Accordingly, a viewing angle of an image displayed in the second mode may be adjusted.

The scan driver 300 may be disposed in the non-display region DP_NDA of the display panel DP. The scan driver 300 receives the first control signal SCS from the driving controller 100. The scan driver 300 outputs initializing scan signals to the initializing scan lines SIL1 to SILn and compensating scan signals to the compensating scan lines SCL1 to SCLn, in response to the first control signal SCS. In addition, the scan driver 300 may output writing scan signals to the write scan lines SWL1 to SWLn and black scan signals to the black scan lines SBL1 to SBLn, in response to the first control signal SCS. Alternatively, the scan driver 300 may include a first scan driver and a second scan driver. The first scan driver may output the initializing scan signals and the compensating scan signals, and the second scan driver may output the writing scan signals and the black scan signals.

The emission driver 350 may be disposed in a non-display region DP_NDA of the display panel DP. The emission driver 350 receives the second control signal ECS from the driving controller 100. The emission driver 350 may output light emission control signals to the emission control lines EML1 to EMLn, in response to the second control signal ECS. Alternatively, the scan driver 300 may be connected to the emission control lines EML1 to EMLn. In this case, the emission driver 350 may be omitted, and the scan driver 300 may output emission control signals to the emission control lines EML1 to EMLn.

The readout circuit 500 receives the fourth control signal RCS from the driving controller 100. The readout circuit 500 may receive sensing signals from the readout lines RL1 to RLh in response to the fourth control signal RCS. The readout circuit 500 may process sensing signals received from the readout lines RL1 to RLh and may provide the processed sensing signals S_FS to the driving controller 100. The driving controller 100 may recognize biometric information based on the sensing signals S_FS.

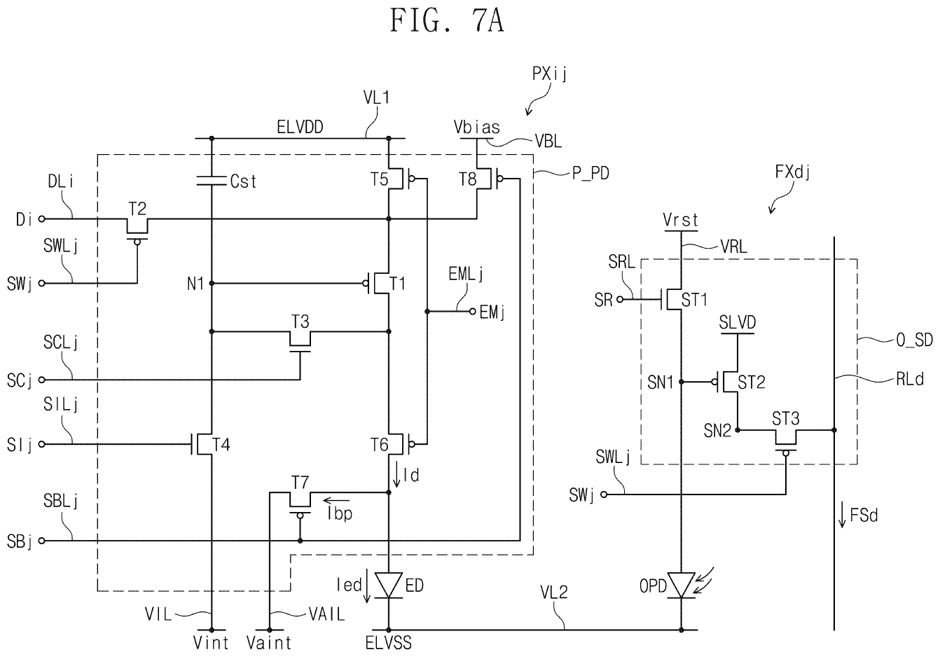

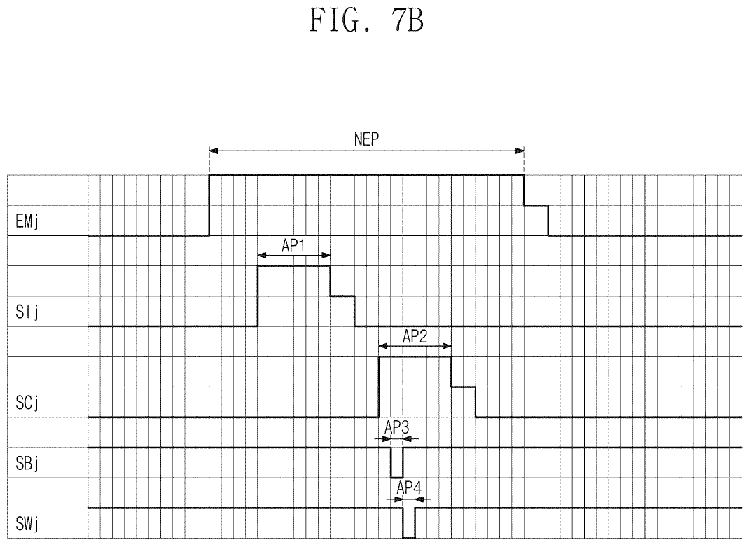

FIG. 7A is a circuit diagram illustrating a pixel and a sensor according to an embodiment of the present disclosure, and FIG. 7B is a timing diagram illustrating a waveform to describe the operations of the pixel and the sensor illustrated in FIG. 7A.

FIG. 7A illustrates an equivalent circuit diagram of one pixel PXij of the plurality of pixels PX_W and PX_N illustrated in FIG. 6. Since each of the plurality of pixels PX_W and PX_N has the same circuit structure, the pixel PXij will be representatively described, and to the extent that an element is not described in detail with respect to this figure, it may be understood that the element is at least similar to a corresponding element that has been described elsewhere within the present disclosure. In addition, FIG. 7A illustrates an equivalent circuit diagram of one sensor FXdj of the plurality of sensors FX illustrated in FIG. 6. Since each of the plurality of sensors FX has the same circuit structure, the sensor FXdj will be representatively described, and to the extent that an element is not described in detail with respect to this figure, it may be understood that the element is at least similar to a corresponding element that has been described elsewhere within the present disclosure.

Referring to FIG. 7A, the pixel PXij is connected to an i-th data line DLi among the data lines DL1 to DLm, a j-th initializing scan line SILj among the initializing scan lines SIL1 to SILn, a j-th compensating scan line SCLj among the compensating scan lines SCL1 to SCLn, a j-th write scan line SWLj among the write scan lines SWL1 to SWLn, a j-th black scan line SBLj among the black scan lines SBL1 to SBLn, and a j-th emission control line EMLj among the emission control lines EML1 to EMLn.

The pixel PXij includes a light emitting element ED and a pixel driving circuit P_PD. The light emitting element ED may be a light emitting diode. According to an embodiment of the present disclosure, the light emitting element ED may be an organic light emitting diode (OLED) including an organic emission layer.

The pixel driving circuit P_PD includes first to eighth transistors T1 to T8 and one capacitor Cst. At least one of the first to eighth transistors T1 to T8 may be a transistor having a low-temperature polycrystalline silicon (LTPS) semiconductor layer. Some of the first to eighth transistors T1 to T8 may be P-type transistors, and the remaining transistors of the first to eighth transistors T1 to T8 may be N-type transistors. At least one of the first to eighth transistors T1 to T8 may be a transistor having an oxide semiconductor layer. For example, the third and fourth transistors T3 and T4 may be oxide semiconductor transistors, and the first, second, and fifth to eighth transistors T1, T2, and T5 to T8 may be LTPS transistors. The third and fourth transistors T3 and T4 may be NMOS transistors.

The configuration of the pixel driving circuit P_PD, according to an embodiment of the present disclosure, is not necessarily limited to the example illustrated in FIG. 7A. The pixel driving circuit P_PD illustrated in FIG. 7A is merely one example, and the configuration of the pixel driving circuit P_PD may be implemented in a modified form. For example, all of the first, second, and fifth to eighth transistors T1, T2, and T5 to T8 may be P-type transistors or N-type transistors.

The j-th initializing scan line SILj, the j-th compensating scan line SCLj, the j-th write scan line SWLj, the j-th black scan line SBLj, and the j-th emission control line EMLj may transmit a j-th initializing scan signal SIj, a j-th compensating scan signal SCj, a j-th write scan signal SWj, a j-th black scan signal SBj, and a j-th emission control signal EMj to the pixel PXij, respectively. The i-th data line DLi is to transmit an i-th data signal Di to the pixel PXij. The i-th data signal Di may have a voltage level corresponding to the image signal RGB input to the display device DD (see FIG. 6).

According to an embodiment of the present disclosure, the pixel PXij may be connected to first and second driving voltage lines VL1 and VL2, first and second initializing voltage lines VIL and VAIL, and a bias voltage line VBL. The first driving voltage line VL1 may be to transmit the first driving voltage ELVDD to the pixel PXij, and the second driving voltage line VL2 may be to transmit the second driving voltage ELVSS to the pixel PXij. In addition, the first initializing voltage line VIL may be to transmit the first initializing voltage Vint to the pixel PXij, and the second initializing voltage line VAIL may be to transmit the second initializing voltage Vaint to the pixel PXij. The bias voltage line VBL may be to transmit the bias voltage Vbias to the pixel PXij.

The first transistor T1 is connected between the first driving voltage line VL1, which receives the first driving voltage ELVDD, and the light emitting element ED. The first transistor T1 includes a first electrode connected to the first driving voltage line VL1 via the fifth transistor T5, a second electrode connected to an anode electrode of the light emitting element ED via the sixth transistor T6, and a third electrode (for example, a gate electrode) connected to one terminal (for example, a first node N1) of the capacitor Cst. The first transistor T1 may receive an i-th data signal Di received through the i-th data line DLi depending on a switching operation of the second transistor T2, and may supply a driving current Id to the light emitting element ED.

The second transistor T2 is connected between the i-th data line DLi and the first electrode of the first transistor T1. The second transistor T2 includes a first electrode connected to the i-th data line DLi, a second electrode connected to the first electrode of the first transistor T1, and a third electrode (for example, a gate electrode) connected to the j-th write scan line SWLj. The second transistor T2 may be turned on in response to the j-th write scan signal SWj received through the j-th write scan line SWLj, and may transmit the i-th data signal Di, which is received through the i-th data line DLi, to the first electrode of the first transistor T1.

The third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (for example, a gate electrode) connected to the j-th compensating scan line SCLj. The third transistor T3 may be turned on in response to the j-th compensating scan signal SCj received through the j-th compensating scan line SCLj, and may connect the third electrode and the second electrode of the first transistor T1 to each other to diode-connect the first transistor T1.

The fourth transistor T4 is connected between the first initializing voltage line VIL for applying the first initializing voltage Vint and the first node N1. The fourth transistor T4 includes a first electrode connected to the first initializing voltage line VIL for applying the first initializing voltage Vint, a second electrode connected to the first node N1, and a third electrode (for example, a gate electrode) connected to the j-th initializing scan line SILj. The fourth transistor T4 is turned on in response to the j-th initializing scan signal SIj received through the j-th initializing scan line SILj. The fourth transistor T4, which is turned on, transmits the first initializing voltage Vint to the first node N1, thereby initializing a potential (that is, the potential of the first node N1) of the third electrode of the first transistor T1.

The fifth transistor T5 includes a first electrode connected to the first driving voltage line VL1, a second electrode connected to the first electrode of the first transistor T1, and a third electrode (for example, a gate electrode) connected to the j-th emission control line EMLj.

The sixth transistor T6 includes a first electrode connected to the second electrode of the first transistor T1, a second electrode connected to the anode electrode of the light emitting element ED, and a third electrode (for example, a gate electrode), connected to the j-th emission control line EMLj.

The fifth and sixth transistors T5 and T6 are simultaneously turned on in response to the j-th emission control signal EMj received through the j-th emission control line EMLj. The first driving voltage ELVDD applied through the fifth transistor T5, which is turned on, may be compensated through the diode-connected first transistor T1 and may be transmitted to the light emitting element ED.

The seventh transistor T7 includes a first electrode connected to the second initializing voltage line VAIL for transmitting the second initializing voltage Vaint, a second electrode connected to the second electrode of the sixth transistor T6, and a third electrode (for example, a gate electrode) connected to the j-th black scan line SBLj. The second initializing voltage Vaint may have a voltage level equal to or lower than the first initializing voltage Vint.

The eighth transistor T8 includes a first electrode connected to the bias voltage line VBL for transmitting the bias voltage Vbias, a second electrode connected to the first electrode of the first transistor T1, and a third electrode (for example, a gate electrode) connected to the j-th black scan line SBLj.

The seventh and eighth transistors T7 and T8 are simultaneously turned on in response to the j-th black scan signal SBj received through the j-th black scan line SBLj. The second initializing voltage Vaint applied through the seventh transistor T7, which is turned on, may be transmitted to the anode electrode of the light emitting element ED. Accordingly, the anode electrode of the light emitting element ED may be initialized with the second initializing voltage Vaint. The bias voltage Vbias applied through the turned-on eighth transistor T8 may be transmitted to the first electrode of the first transistor T1. Accordingly, the bias voltage Vbias may be periodically applied to the first electrode of the first transistor T1, thereby preventing display quality from being degraded as a potential difference between the first and second electrodes of the first transistor T1 is increased to at least a specific level due to a hysteresis phenomenon.

A first terminal of the capacitor Cst is connected to the third electrode of the first transistor T1 as described above, and a second terminal of the capacitor Cst is connected to the first driving voltage line VL1. A cathode electrode of the light emitting element ED may be connected to the second driving voltage line VL2 for transmitting the second driving voltage ELVSS. The second driving voltage ELVSS may have a voltage level that is lower than a voltage level of the first driving voltage ELVDD. According to an embodiment of the present disclosure, the second driving voltage ELVSS may have the voltage level that is lower than voltage levels of the first and second initializing voltages Vint and Vaint.

Referring to FIGS. 7A and 7B, the j-th emission control signal EMj has a high level during a non-emission period NEP. Within the non-emission period NEP, the j-th initializing scan signal SIj is activated. When the j-th initializing scan signal SIj having the high level is provided through the j-th initializing scan line SILj during an activation period AP1 (hereinafter, a first activation period) of the j-th initializing scan signal SIj, the fourth transistor T4 is turned on in response to the j-th initializing scan signal SIj having the high level. The first initializing voltage Vint is transmitted to the third electrode of the first transistor T1 through the fourth transistor T4 which is turned on, and the first node N1 is initialized with the first initializing voltage Vint. Accordingly, the first activation period AP1 may be defined as an initializing period of a pixel PXij.

Next, when the j-th compensating scan signal SCj is activated, and when the j-th compensating scan signal SCj having a high level is supplied through the j-th compensating scan line SCLj during an activation period AP2 (hereinafter, a second activation period) of the j-th compensating scan signal SCj, the third transistor T3 is turned on. The first transistor T1 is diode-connected by the third transistor T3 turned on and is forward-biased. The first activation period AP1 may be in a non-overlap state with the second activation period AP2.

Within the second activation period AP2, the j-th write scan signal SWj is activated. The j-th write scan signal SWj has a low level during an activation period AP4 (hereinafter, a fourth activation period). During the fourth activation period AP4, the second transistor T2 is turned on in response to the j-th write scan signal SWj having the low level. Then, a compensating voltage “Di-Vth”, which is obtained by subtracting the threshold voltage Vth of the first transistor T1 from the i-th data signal Di, which is supplied through the i-th data line DLi, is applied to the third electrode of the first transistor T1. For example, a potential of the third electrode of the first transistor T1 may be the compensating voltage “Di-Vth”. The fourth activation period AP4 may overlap the second activation period AP2. The duration of the second activation period AP2 may be greater than the duration of the fourth activation period AP4.

The first driving voltage ELVDD and the compensating voltage “Di-Vth” may be applied to both terminals of the capacitor Cst, and charges corresponding to a voltage difference between these terminals may be stored in the capacitor Cst. In this case, a high-level period of the j-th compensating scan signal SCj may be referred to as a compensating period of the pixel PXij.

Within the second activation period AP2 of the j-th compensating scan signal SCj, the j-th black scan signal SBj is activated. The j-th black scan signal SBj has a low level during an activation period AP3 (hereinafter, a third activation period). During the third activation period AP3, the seventh transistor T7 is turned on by receiving the j-th black scan signal SBj having a low level through the j-th black scan line SBLj. A portion of the driving current Id may flow out as a bypass current Ibp through the seventh transistor T7, by the seventh transistor T7. The third activation period AP3 may be overlapped with the second activation period AP2. The duration of the second activation period AP2 may be greater than the duration of the third activation period AP3. The third activation period AP3 may precede the fourth activation period AP4 and may be in the non-overlap state with the fourth activation period AP4.

When the pixel PXij displays a black image, even if the minimum driving current of the first transistor T1 flows as the driving current Id, the light emitting element ED may emit light. In this case, the pixel PXij is unable to display the black image normally. Accordingly, the seventh transistor T7 in the pixel PXij, according to an embodiment of the present disclosure, may divert a portion, which serves as the bypass current Ibp, of the minimum driving current of the first transistor T1, to another current path other than a current path toward the light emitting element ED. In this case, the minimum driving current of the first transistor T1 refers to a current flowing through the first transistor T1, under a condition that a gate-to-source voltage Vgs of the first transistor T1 is smaller than the threshold voltage Vth such that the first transistor T1 is turned off. Under the condition that the first transistor T1 is turned off, the minimum driving current (for example, a current of 10 pA or less) flowing through the first transistor T1 is transmitted to the light emitting element ED, such that an image having a black grayscale level is displayed. When the pixel PXij displays a black image, the influence of the bypass current Ibp on the minimum driving current is relatively significant. However, when an image such as a general image or a white image is displayed, the influence of the bypass current Ibp on the driving current Id is negligible. Accordingly, when the black image is displayed, a current (that is, the light emitting current Ied), which is obtained by subtracting a current amount of the bypass current Ibp flowing out through the seventh transistor T7 from the driving current Id, is provided to the light emitting element ED to firmly express the black image. Accordingly, the pixel PXij may implement a black grayscale level image using the seventh transistor T7. Accordingly, a contrast ratio may be improved.

Next, the j-th emission control signal EMj supplied from the j-th emission control line EMLj is changed from a high level to a low level. The fifth and sixth transistors T5 and T6 are turned on in response to the j-th emission control signal EMj having a low level. Then, the driving current Id is generated based on the voltage difference between the voltage of the third electrode of the first transistor T1 and the first driving voltage ELVDD, and the driving current Id is supplied to the light emitting element ED through the sixth transistor T6 such that the light emitting current Ied flows through the light emitting element ED.

Referring again to FIG. 7A, the sensor FXdj is connected to a d-th readout line RLd among the readout lines RL1 to RLh, the j-th write scan line SWLj, and a reset control line SRL.

The sensor FXdj includes a light receiving element OPD and a sensor driving circuit O_SD. According to an embodiment of the present disclosure, the light receiving element OPD may be an organic photodiode including an organic material as a photoelectric conversion layer. Although FIG. 7A illustrates the structure that the sensor FXdj includes one light receiving element OPD, the present disclosure is not necessarily limited thereto. For example, the sensor FXdj may include a plurality of light receiving elements OPD connected in parallel to each other.

An anode electrode of the light receiving element OPD is connected to a first sensing node SN1, and a cathode electrode of the light receiving element OPD may be connected to the second driving voltage line VL2 which is used to transmit the second driving voltage ELVSS. The cathode electrode of the light receiving element OPD may be electrically connected to the cathode electrode of the light emitting element ED. According to an embodiment of the present disclosure, the cathode electrode of the light receiving element OPD may be integrally formed with the cathode electrode of the light emitting element ED to form a common cathode electrode.

The sensor driving circuit O_SD includes three transistors ST1 to ST3. The three transistors ST1 to ST3 may respectively be a reset transistor ST1, an amplifying transistor ST2, and an output transistor ST3. At least one of the reset transistor ST1, the amplifying transistor ST2, or the output transistor ST3 may be an oxide semiconductor transistor. According to an embodiment of the present disclosure, the reset transistor ST1 may be an oxide semiconductor transistor, and the amplifying transistor ST2 and the output transistor ST3 may be LTPS transistors. However, the present disclosure is not necessarily limited thereto. For example, the reset transistor ST1 and the output transistor ST3 may be oxide semiconductor transistors, and the amplifying transistor ST2 may be an LTPS transistor.

In addition, some of the reset transistor ST1, the amplifying transistor ST2, and the output transistor ST3 may be P-type transistors, and some of the reset transistor ST1, the amplifying transistor ST2, and the output transistor ST3 may be N-type transistors. According to an embodiment of the present disclosure, the amplifying transistor ST2 and the output transistor ST3 may be PMOS transistors, and the reset transistor ST1 may be an NMOS transistor. However, the present disclosure is not necessarily limited thereto. For example, the reset transistor ST1, the amplifying transistor ST2, and the output transistor ST3 may all be N-type transistors or may all be P-type transistors.

A part (for example, the reset transistor ST1) of the reset transistor ST1, the amplifying transistor ST2, and the output transistor ST3 may be a transistor in a type the same as the types of the third and fourth transistors T3 and T4 of the pixel PXij. The amplifying transistor ST2 and the output transistor ST3 may be transistors in types the same as types of the first, second, and fifth to eighth transistors T1, T2, and T5 to T8 of the pixel PXij.

The circuit configuration of the sensor driving circuit O_SD, according to the present disclosure, is not necessarily limited to FIG. 7A. The sensor driving circuit O_SD illustrated in FIG. 7A is provided for an illustrative purpose, and the configuration of the sensor driving circuit O_SD may be modified and implemented.

The reset transistor ST1 includes a first electrode, which receives a reset voltage Vrst, a second electrode connected to the first sensing node SN1, and a third electrode which receives the reset control signal SR. The reset transistor ST1 may reset a potential of the first sensing node SN1 to the reset voltage Vrst in response to the reset control signal SR. The reset control signal SR may be a signal provided through the reset control line SRL. However, the present disclosure is not necessarily limited thereto. Alternatively, the reset control signal SR may be the j-th compensating scan signal SCj supplied through the j-th compensating scan line SCLj. For example, the reset transistor ST1 may receive the j-th compensating scan signal SCj, which is supplied from the j-th compensating scan line SCLj, as the reset control signal SR. According to an embodiment of the present disclosure, the reset voltage Vrst may have a voltage level that is lower than a voltage level of the second driving voltage ELVSS at least during the activation period of the reset control signal SR. The reset voltage Vrst may be transmitted to the sensor FXdj through the reset voltage line VRL. The reset voltage Vrst may be a DC voltage maintained to be at a voltage level that is lower than a voltage level of the second driving voltage ELVSS.

The reset transistor ST1 may include a plurality of sub-reset transistors connected in series to each other. For example, the reset transistor ST1 may include two sub-reset transistors (hereinafter, referred to as “first and second sub-reset transistors). In this case, a third electrode of the first sub-reset transistor and a third electrode of the second sub-reset transistor are connected to the reset control line SRL. In addition, a second electrode of the first sub-reset transistor and a first electrode of the second sub-reset transistor may be electrically connected to each other. In addition, the reset voltage Vrst may be applied to the first electrode of the first sub-reset transistor, and the second electrode of the second sub-reset transistor may be electrically connected to the first sensing node SN1. However, the number of sub-reset transistors is not necessarily limited thereto, and may be variously modified.

The amplifying transistor ST2 includes a first electrode to receive a sensing driving voltage SLVD, a second electrode connected to the second sensing node SN2, and a third electrode connected to the first sensing node SN1. The amplifying transistor ST2 may be turned on based on the potential of the first sensing node SN1 to apply the sensing driving voltage SLVD to the second sensing node SN2. According to an embodiment of the present disclosure, the sensing driving voltage SLVD may be one of the first driving voltage ELVDD, and the first and second initializing voltages Vint and Vaint. When the sensing driving voltage SLVD is the first driving voltage ELVDD, the first electrode of the amplifying transistor ST2 may be electrically connected to the first driving voltage line VL1. When the sensing driving voltage SLVD is the first initializing voltage Vint, the first electrode of the amplifying transistor ST2 may be connected to the first initializing voltage line VIL. When the sensing driving voltage SLVD is the second initializing voltage Vaint, the first electrode of the amplifying transistor ST2 may be electrically connected to the second initializing voltage line VAIL.

The output transistor ST3 includes a first electrode connected to the second sensing node SN2, a second electrode connected to the d-th readout line RLd, and a third electrode to receive the output control signal. The output transistor ST3 may transmit the sensing signal FSd to the d-th readout line RLd in response to the output control signal. The output control signal may be the j-th write scan signal SWj supplied through the j-th write scan line SWLj. For example, the output transistor ST3 may receive the j-th write scan signal SWj, which is supplied from the j-th write scan line SWLj, as the output control signal.

The light receiving element OPD of the sensor FXdj may be exposed to light during a light-emitting period of the light emitting element ED. The light may be emitted from the light emitting element ED.

When a user's hand touches the display surface IS (see FIG. 1A), the light receiving element OPD generates photocharges corresponding to light reflected by a fingerprint ridge or a fingerprint valley between the fingerprint ridges. An amount of current flowing through the light receiving element OPD is varied depending on the generated photocharges. When the light receiving element OPD receives light reflected by the fingerprint ridge, a current flowing through the light receiving element OPD may be referred to as a first current. When the light receiving element OPD receives light reflected by the fingerprint valley, a current flowing through the light receiving element OPD may be referred to as a second current. An amount of light reflected by the fingerprint ridge is different from an amount of the light reflected by the fingerprint valley. Accordingly, this difference in the amount of light appears as a difference between the first current and the second current. When the first current flows through the light receiving element OPD, a potential of the first sensing node SN1 may be referred to as a first potential. When the second current flows through the light receiving element OPD, a potential of the first sensing node SN1 may be referred to as a second potential. According to an embodiment of the present disclosure, the first current may be greater than the second current. In this case, the first potential may be lower than the second potential.

The amplifying transistor ST2 may be a source follower amplifier to generate a source-drain current in proportion to the potential, which is input to the third electrode, of the first sensing node SN1.

During the fourth activation period AP4, the j-th write scan signal SWj having a low level is supplied to the output transistor ST3 through the j-th write scan line SWLj. When the output transistor ST3 is turned on in response to the j-th write scan signal SWj having the low level, the sensing signal FSd corresponding to a current flowing through the amplifying transistor ST2 may be output to the d-th readout line RLd.

Next, during the reset period, the reset transistor ST1 is turned on when the reset control signal SR having a high level is supplied through the reset control line SRL. The reset period may be defined as an activation period (for example, a high level period) of the reset control signal SR. Alternatively, when the reset transistor ST1 is formed of the P-type transistor, the reset control signal SR having a low level may be supplied to the reset control line SRL during the reset period. During the reset period, the first sensing node SN1 may be reset with a potential corresponding to the reset voltage Vrst. According to an embodiment of the present disclosure, the reset voltage Vrst may have a voltage level that is lower than a voltage level of the second driving voltage ELVSS.

Next, when the reset period is terminated, the light receiving element OPD may generate photocharges corresponding to the received light, and the generated photocharges may be accumulated in the first sensing node SN1.

Thus, a dual-mode display device may be integrated into a vehicle, which includes independently controlled first and second display regions positioned in front of the driver and passenger, respectively. Each region can switch between a wide-angle public mode and a narrow-angle privacy mode, restricting the visibility of certain information depending on the viewer's position. The system can automatically switch the passenger-side display to privacy mode when the vehicle exceeds a set speed, preventing the driver from being distracted by content like movies, while still allowing personalized information to be shown to each occupant under controlled conditions.

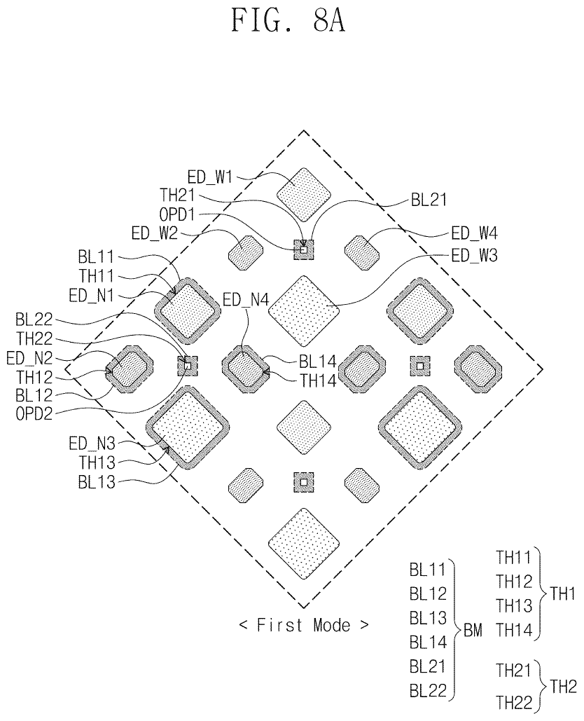

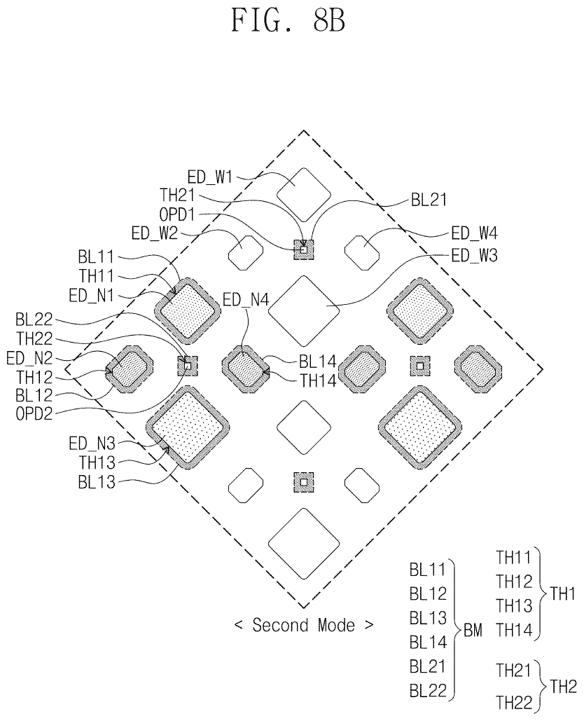

FIG. 8A is a plan view illustrating a display panel operating in a first mode according to an embodiment of the present disclosure, and FIG. 8B is a plan view illustrating a display panel operating in a second mode according to an embodiment of the present disclosure.

Referring to FIGS. 8A and 8B, the plurality of pixels PX_W and PX_N (see FIG. 6) are disposed in the display panel DP. Each of the pixels PX_W and PX_N may include a light emitting element. Some of the pixels PX_W and PX_N may be wide pixels PX_W (or first-type pixels), and remaining pixels of the pixels PX_W and PX_N may be narrow pixels PX_N (or second-type pixels). Each of the wide pixels PX_W includes a (1-1)-th pixel, a (1-2)-th pixel, a (1-3)-th pixel, and a (1-4)-th pixel, and each of the narrow pixels PX_N includes a (2-1)-th pixel, a (2-2)-th pixel, a (2-3)-th pixel, and a (2-4)-th pixel.

The (1-1)-th pixel, the (1-2)-th pixel, the (1-3)-th pixel, and the (1-4)-th pixel include a (1-1)-th light emitting element ED_W1, a (1-2)-th light emitting element ED_W2, a (1-3)-th light emitting element ED_W3, and a (1-4)-th light emitting element ED_W4, respectively. The (2-1)-th pixel, the (2-2)-th pixel, the (2-3)-th pixel, and the (2-4)-th pixel include a (2-1)-th light emitting element ED_N1, a (2-2)-th light emitting element ED_N2, a (2-3)-th light emitting element ED_N3, and a (2-4)-th light emitting element ED_N4, respectively. The (1-1)-th light emitting element ED_W1 and the (2-1)-th light emitting element ED_N1 output first color light (for example, red light). The (1-2)-th light emitting element ED_W2, the (2-2)-th light emitting element ED_N2, the (1-4)-th light emitting element ED_W4, and the (2-4)-th light emitting element ED_N4 output second color light (for example, green light). The (1-3)-th light emitting element ED_W3 and the (2-3)-th light emitting element ED_N3 output third color light (for example, blue light).

Each of the (1-1)-th light emitting element ED_W1, the (2-1)-th light emitting element ED_N1, the (1-3)-th light emitting element ED_W3, and the (2-3)-th light emitting element ED_N3 may have a square shape and four rounded corners. However, the present disclosure is not necessarily limited thereto. For example, each of the (1-1)-th light emitting element ED_W1, the (2-1)-th light emitting element ED_N1, the (1-3)-th light emitting element ED_W3, and the (2-3)-th light emitting element ED_N3 may have an octagonal shape. Each of the (1-2)-th light emitting element ED_W2, the (2-2)-th light emitting element ED_N2, the (1-4)-th light emitting element ED_W4, and the (2-4)-th light emitting element ED_N4 may have a rectangle shape and four rounded corners. However, the present disclosure is not necessarily limited thereto. For example, each of the (1-2)-th light emitting element ED_W2, the (2-2)-th light emitting element ED_N2, the (1-4)-th light emitting element ED_W4, and the (2-4)-th light emitting element ED_N4 may have an octagonal shape, a circular shape, or an oval shape.

The (1-1)-th pixel, the (1-2)-th pixel, the (1-3)-th pixel, and the (1-4)-th pixel may constitute one wide pixel unit (hereinafter, referred to as a “first pixel unit”), and the (2-1)-th pixel, the (2-2)-th pixel, the (2-3)-th pixel, and the (2-4)-th pixel may constitute one narrow pixel unit (hereinafter, referred to as a “second pixel unit”).

The plurality of sensors FX (see FIG. 6) may include a first sensor and a second sensor. The first sensor includes a first light receiving element OPD1, and the second sensor includes a second light receiving element OPD2. The first light receiving element OPD1 may be surrounded by the (1-1)-th light emitting element ED_W1, the (1-2)-th light emitting element ED_W2, the (1-3)-th light emitting element ED_W3, and the (1-4)-th light emitting element ED_W4, and the second light receiving element OPD2 may be surrounded by the (2-1)-th light emitting element ED_N1, the (2-2)-th light emitting element ED_N2, the (2-3)-th light emitting element ED_N3, and the (2-4)-th light emitting element ED_N4. According to an embodiment of the present disclosure, each of the first and second light receiving elements OPD1 and OPD2 may have a square shape. However, the present disclosure is not necessarily limited thereto. For example, each of the first and second light receiving elements OPD1 and OPD2 may have a rectangular shape, a circular shape, or an oval shape.

The display device DD (see FIG. 6) may display an image using the first pixel unit and the second pixel unit in the first mode. In the second mode, the first pixel unit is turned off, so the display device DD may display an image only using the second pixel unit.

The optical path control layer OSL (see FIG. 5) is disposed on the display panel DP. The optical path control layer OSL may include a light blocking layer BM having a ring shape. The light blocking layer BM includes (1-1)-th to (1-4)-th light blocking rings BL11, BL12, BL13, and BL14 surrounding the (2-1)-th light emitting element ED_N1, the (2-2)-th light emitting element ED_N2, the (2-3)-th light emitting element ED_N3, and the (2-4)-th light emitting element ED_N4. The light blocking layer BM may further include the (2-1)-th light blocking ring BL21 and the (2-2)-th light blocking ring BL22 surrounding the first and second light receiving elements OPD1 and OPD2, respectively. FIGS. 8A and 8B illustrate the (1-1)-th to (1-4)-th light blocking rings BL11, BL12, BL13, and BL14 separated from each other. However, the embodiments of the present disclosure are not necessarily limited thereto. For example, the (1-1)-th to (1-4)-th light blocking rings BL11, BL12, BL13, and BL14, and the (2-2)-th light blocking ring BL22 are connected to each other to have an integral shape, e.g., a shape that is singular, continuous, and uninterrupted.

The light blocking layer BM may include a first transmission hole TH1 corresponding to the light emitting elements ED_N1 to ED_N4 in the second pixel unit, and a second transmission hole TH2 corresponding to the light receiving elements OPD1 and OPD2. The first transmission hole TH1 includes a (1-1)-th transmission hole TH11, a (1-2)-th transmission hole TH12, a (1-3)-th transmission hole TH13, and a (1-4)-th transmission hole TH14 corresponding to the (2-1)-th light emitting element ED_N1, the (2-2)-th light emitting element ED_N2, the (2-3)-th light emitting element ED_N3, and the (2-4)-th light emitting element ED_N4, respectively. The second transmission hole TH2 includes a (2-1)-th transmission hole TH21 and a (2-2)-th transmission hole TH22 corresponding to the first and second light receiving elements OPD1 and OPD2, respectively.

The (1-1)-th transmission hole TH11 to the (1-4)-th transmission hole TH14 are disposed in the (1-1)-th to (1-4)-th light blocking rings BL11, BL12, BL13, and BL14, respectively, and the (2-1)-th transmission hole TH21 and the (2-2)-th transmission hole TH22 are disposed in the (2-1)-th light blocking ring BL21 and the (2-2)-th light blocking ring BL22, respectively. Each of the (1-1)-th to (1-4)-th light blocking rings BL11, BL12, BL13, and BL14 may control a viewing angle of light emitted from a relevant one of the (2-1)-th light emitting element ED_N1 to (2-4)-th light emitting element ED_N4, respectively. The (2-1)-th light blocking ring BL21 and the (2-2)-th light blocking ring BL22 may control the range (size or area) of an image (or fingerprint) capturing region obtained by the first and second light receiving elements OPD1 and OPD2.

Thus, the display panel includes two types of pixels: wide pixels (an example of “first-type pixels”) and narrow pixels (an example of “second-type pixels”), each made up of sub-pixels that emit red, green, or blue light, and are arranged into pixel units. In the wide-viewing first mode, both pixel types are active to display images, while in the narrow-viewing second mode, only the narrow pixels are used, with the wide pixels turned off. A light blocking layer with ring-shaped structures and precisely aligned transmission holes is placed over the narrow pixels and optical sensors to limit light emission and control viewing angles and sensor capture ranges, thereby enabling privacy viewing and enhancing sensing accuracy.

FIG. 9A is a cross-sectional view illustrating a (2-2)-th light emitting element, a (2-4)-th light emitting element, and a second light receiving element according to an embodiment of the present disclosure. FIG. 9B is a cross-sectional view illustrating a (1-2)-th light emitting element, a (1-4)-th light emitting element, and a first light receiving element according to an embodiment of the present disclosure. FIG. 9C is a cross-sectional view illustrating a (1-2)-th light emitting element, a (1-4)-th light emitting element, and a first light receiving element according to an embodiment of the present disclosure.

Referring to FIGS. 9A and 9B, the display panel DP may include the base layer BS, the circuit layer DP_CL, the element layer DP_ED, and the encapsulating layer TFE.

The base layer BS may include a synthetic resin layer. The synthetic resin layer may include thermosetting resin. In particular, the synthetic resin layer may be a polyimide-based resin layer, and the material thereof is not particularly limited. The synthetic resin layer may include at least one of acrylate-based resin, methacrylate-based resin, polyisoprene-based resin, vinyl-based resin, epoxy-based resin, urethane-based resin, cellulose-based resin, siloxane-based resin, polyamide-based resin, or perylene-based resin. In addition, the base layer BS may include a glass substrate, a metal substrate, or an organic/inorganic composite substrate.

At least one inorganic layer is formed on a top surface of the base layer BS. The inorganic layer may include at least one of aluminum oxide, titanium oxide, silicon oxide, silicon oxynitride, zirconium oxide, or hafnium oxide. The inorganic layer may include multiple layers.

The circuit layer DP_CL is disposed on the base layer BS. The circuit layer DP_CL may include the transistors T1 to T8, and the capacitor Cst of the pixel driving circuit P_PD illustrated in FIG. 7A. In addition, the circuit layer DP_CL may include the transistors ST1 to ST3 of the sensor driving circuit O_SD illustrated in FIG. 7A.

The element layer DP_ED is disposed on the circuit layer DP_CL. The element layer DP_ED may include the (1-1)-th to (1-4)-th light emitting elements ED_W1 to ED_W4, the (2-1)-th to (2-4)-th light emitting elements ED_N1 to ED_N4, and the first and second light receiving elements OPD1 and OPD2. FIG. 9A illustrates the (2-2)-th light emitting element ED_N2, the (2-4)-th light emitting element ED_N4, and the second light receiving element OPD2, and FIGS. 9B and 9C illustrate the (1-2)-th light emitting element ED_W2, the (1-4)-th light emitting element ED_W4, and the first light receiving element OPD1. Other light emitting elements ED_W1, ED_W3, ED_N1, and ED_N3 may have a similar cross-sectional structure, and to the extent that an element is not described in detail with respect to this figure, it may be understood that the element is at least similar to a corresponding element that has been described elsewhere within the present disclosure.

Each of the (1-2)-th light emitting element ED_W2, the (1-4)-th light emitting element ED_W4, the (2-2)-th light emitting element ED_N2, and the (2-4)-th light emitting element ED_N4 may include a pixel anode electrode PEL, an emission layer EML, and a common cathode electrode CEL. Each of the first and second light receiving elements OPD1 and OPD2 may include a sensor anode electrode SEL, a light receiving layer LRL, and the common cathode electrode CEL.

Each of the pixel anode electrode PEL and the sensor anode electrode SEL may include a metal material or a transparent conductive material. The pixel anode electrode PEL may be connected to the second electrode of the sixth transistor T6 illustrated in FIG. 7A. The sensor anode electrode SEL may be connected to the second electrode of the reset transistor ST1 illustrated in FIG. 7A.

The pixel defining layer PDL may be disposed on the circuit layer DP_CL on which the pixel anode electrode PEL and the sensor anode electrode SEL are formed. The pixel defining layer PDL may include a pixel opening part POP to expose a specific portion of the pixel anode electrode PEL and a sensor opening part SOP to expose a specific portion of the sensor anode electrode SEL. Each of the (1-2)-th light emitting element ED_W2, the (1-4)-th light emitting element ED_W4, the (2-2)-th light emitting element ED_N2, and the (2-4)-th light emitting element ED_N4 may have a shape corresponding to the shape of the pixel opening part POP. The first and second light receiving elements OPD1 and OPD2 may have a shape corresponding to the shape of the sensor opening part SOP. According to an embodiment of the present disclosure, the size of the pixel opening part POP may be greater than the size of the sensor opening part SOP.

The pixel defining layer PDL may be an organic insulating layer including an organic material. The organic material may include an acrylic resin, an epoxy resin, a phenolic resin, a polyamide resin, or a polyimide resin. According to an embodiment of the present disclosure, the pixel defining layer PDL may include a photo-absorbing material to absorb light incident from the exterior or a structure applied with a photo-absorber. The photo-absorbing material may include a black pigment based on carbon. The photo-absorber may include an opaque metal material, such as chromium (Cr), molybdenum (Mo), a molybdenum-titanium alloy (MoTi), tungsten (W), vanadium (V), niobium (Nb), tantalum (Ta), manganese (Mn), cobalt (Co), or nickel (Ni), having a high light absorbance.

The emission layer EML is disposed on the pixel anode electrode PEL exposed through the pixel opening part POP. The emission layer EML may include an organic light emitting material and/or an inorganic light emitting material. The emission layer EML in each of the (1-2)-th light emitting element ED_W2, the (1-4)-th light emitting element ED_W4, the (2-2)-th light emitting element ED_N2, and the (2-4)-th light emitting element ED_N4 may generate green light. However, light generated from the emission layer EML may have various colors depending on the type of the light emitting material included in the emission layer EML.

The light receiving layer LRL is disposed on the sensor anode electrode SEL exposed through the sensor opening part SOP. The light receiving layer LRL may emit electrons to correspond to light having a specific wavelength band to sense the intensity of light. The light receiving layer LRL may include a low molecular weight organic material or a high molecular weight organic material. As used herein, “low molecular weight organic material” may represent small-molecule organic compounds, usually with a defined molecular structure and relatively low molecular mass (often under 1,000 Daltons), whereas “high molecular weight organic material” may represent polymeric organic compounds, which are long-chain molecules with a relatively high molecular weight (often in the tens or hundreds of thousands of Daltons).

The common cathode electrode CEL may be disposed on the emission layer EML and the light receiving layer LRL. The common cathode electrode CEL may be commonly provided to the plurality of pixels PX_W and PX_N (see FIG. 6) and the plurality of sensors FX (see FIG. 6). The common cathode electrode CEL may include a transparent conductive material.

The encapsulating layer TFE may be disposed on the element layer DP_ED. The encapsulating layer TFE may include a first inorganic layer IL1, an organic layer OL, and a second inorganic layer IL2 sequentially stacked on each other. The first inorganic layer and the second inorganic layer IL1 and IL2 may include an inorganic material and protect pixels PX_W and PX_N from moisture/oxygen. The organic layer OL may include an organic material and may protect the pixels PX_W and PX_N and the sensors FX from foreign substances such as dust particles.

The input sensing layer ISP may include a base insulating layer BIL, a first conductive layer CL1, an intermediate insulating layer IIL, a second conductive layer CL2, and a cover insulating layer CIL.

The base insulating layer BIL may be an inorganic layer including at least one of silicon nitride, silicon oxynitride, or silicon oxide. Alternatively, the base insulating layer BIL may be an organic layer including an epoxy resin, an acrylate resin, or an imide-based resin. The base insulating layer BIL may have a single-layer structure or may be a multi-layer structure in which a plurality of layers are stacked in the third direction DR3 (see FIG. 5).

Each of the first conductive layer CL1 and the second conductive layer CL2 may have a single-layer structure or a multi-layer structure in which a plurality of layers are stacked in the third direction DR3.

A conductive layer in the single-layer structure may include a metal layer or a transparent conductive layer. The metal layer may include molybdenum, silver, titanium, copper, aluminum, or the alloy thereof. The transparent conductive layer may include a transparent conductive oxide such as indium tin oxide, indium zinc oxide, zinc oxide, or indium zinc tin oxide. In addition, the transparent conductive layer may include conductive polymer, such as PEDOT, a metal nano-wire, or graphene.

The conductive layer in the multi-layer structure may include metal layers. The metal layers may have, for example, a three-layer structure of titanium/aluminum/titanium. The conductive layer in the multi-layer structure may include at least one metal layer and at least one transparent conductive layer.

At least one of the intermediate insulating layer IIL or the cover insulating layer CIL may include an inorganic film. The inorganic film may include at least one of an aluminum oxide, a titanium oxide, a silicon oxide, a silicon nitride, a silicon oxynitride, a zirconium oxide, or a hafnium oxide.

At least one of the intermediate insulating layer IIL or the cover insulating layer CIL may include an organic film. The organic film may include at least one of acrylate-based resin, methacrylate-based resin, polyisoprene-based resin, vinyl-based resin, epoxy-based resin, urethane-based resin, cellulose-based resin, siloxane-based resin, polyimide-based resin, polyamide-based resin, or perylene-based resin.

The optical path control layer OSL may be disposed on the input sensing layer ISP. The optical path control layer OSL may include a color filter layer CFL, a first overcoating layer OCL1, the light blocking layer BM, and a second overcoating layer OCL2.

The color filter layer CFL may include a first color filter CF1, a second color filter CF2, and a third color filter CF3. The first color filter CF1 is referred to as a red color filter, the second color filter CF2 is referred to as a green color filter, and the third color filter CF3 is referred to as a blue color filter. The first color filter CF1 corresponds to the (1-1)-th light emitting element ED_W1 and the (2-1)-th light emitting element ED_N1, and the third color filter CF3 corresponds to the (1-3)-th light emitting element ED_W3 and the (2-3)-th light emitting element ED_N3. The second color filter CF2 corresponds to the (1-2)-th light emitting element ED_W2, the (1-4)-th light emitting element ED_W4, the (2-2)-th light emitting element ED_N2, and the (2-4)-th light emitting element ED_N4.

The color filter layer CFL may further include a dummy color filter DCF. The dummy color filter DCF may correspond to the first and second light receiving elements OPD1 and OPD2. According to an embodiment of the present disclosure, the dummy color filter DCF may have the same color as the second color filter CF2. The first to third color filters CF1, CF2, and CF3 correspond to emission regions defined by the light emitting elements, respectively, and the dummy color filter DCF corresponds to the sensing region defined by the light receiving elements.

The color filter layer CFL may further include a light blocking filter BCF disposed in the non-emission region. The light blocking filter BCF has a structure in which at least two color filters having mutually different colors are stacked. According to an embodiment of the present disclosure, although the light blocking filter BCF has a structure in which the first color filter CF1 and the third color filter CF3 overlap with each other, the present disclosure is not necessarily limited thereto. The light blocking filter BCF may be in a non-overlap state with the light emitting elements and the light receiving elements.

The first overcoating layer OCL1 is disposed on the color filter layer CFL. The first overcoating layer OCL1 may be a planarization layer which removes a step difference between the color filters CF1 to CF3. The first overcoating layer OCL1 may be formed in an inkjet manner. A capping layer CPL may be disposed on the first overcoating layer OCL1, and the light blocking layer BM may be disposed on the capping layer CPL. Alternatively, the capping layer CPL may be omitted. When the capping layer CPL is omitted, the light blocking layer BM may be directly formed on the first overcoating layer OCL1.

The light blocking layer BM may surround an emission region in each of the (1-2)-th light emitting element ED_W2, the (1-4)-th light emitting element ED_W4, the (2-2)-th light emitting element ED_N2, and the (2-4)-th light emitting element ED_N4. In addition, the light blocking layer BM may surround a light receiving region for each of the first and second light receiving elements OPD1 and OPD2. The light blocking layer BM may absorb or block light incident thereto from the outside. The light blocking layer BM may include an organic light blocking material. For example, the organic light blocking material may include one of carbon black and titan black, but the present disclosure is not necessarily limited thereto. The light blocking layer BM may overlap the pixel defining layer PDL.

The light blocking layer BM may be disposed therein with a plurality of first transmission holes TH1 (see FIG. 8A) and a plurality of second transmission holes TH2 (see FIG. 8A). FIG. 9A illustrates the (1-2)-th transmission hole TH12 and the (1-4)-th transmission hole TH14, which correspond to the (2-2)-th light emitting element ED_N2 and the (2-4)-th light emitting element ED_N4, of the plurality of first transmission holes TH1. The second transmission holes TH2 include the (2-1)-th transmission hole TH21 corresponding to the first light receiving elements OPD1 and the (2-2)-th transmission hole TH22 corresponding to the second light receiving elements OPD2. The light blocking layer BM may be further disposed therein with a plurality of third transmission holes corresponding to the (1-1)-th light emitting element ED_W1, the (1-2)-th light emitting element ED_W2, the (1-3)-th light emitting element ED_W3, and the (1-4)-th light emitting element ED_W4. FIG. 9B illustrates a (3-2)-th transmission hole TH32 and a (3-4)-th transmission hole TH34, which correspond to the (1-2)-th light emitting element ED_W2 and the (1-4)-th light emitting element ED_W4, respectively, of the plurality of third transmission holes.

According to an embodiment of the present disclosure, each of the (1-2)-th transmission hole TH12 and the (1-4)-th transmission hole TH14 may have the size greater than the size of the (2-2)-th transmission hole TH22. The size of the (1-2)-th transmission hole TH12 may be smaller than the size of the pixel opening part POP, which corresponds to the (2-2)-th light emitting element ED_N2, defined in the pixel defining layer PDL. The size of the (1-4)-th transmission hole TH14 may be smaller than the size of the pixel opening part POP, which corresponds to the (2-4)-th light emitting element ED_N4, defined in the pixel defining layer PDL. The sizes of the (2-1)-th transmission hole TH21 and the (2-2)-th transmission hole TH22 may be smaller than the size of the sensor opening part SOP, which corresponds to the first and second light receiving elements OPD1 and OPD2, defined in the pixel defining layer PDL.

As the size of each of the (1-2)-th transmission hole TH12 and the (1-4)-th transmission hole TH14 is formed to be smaller than the size of the pixel opening part POP, the range of the viewing angle of light output from each of the (2-2)-th light emitting element ED_N2 and (2-4)-th light emitting element ED_N4 may be reduced by the light blocking layer BM. Accordingly, when the display device DD (see FIG. 6) operates in the second mode, the display device DD may display an image with the second viewing angle that is narrower than the first viewing angle.

As the size of each of the (3-2)-th transmission hole TH32 and the (3-4)-th transmission hole TH34 is formed to be equal to or greater than the size of the pixel opening part POP, the range of the viewing angle of light output from each of the (1-2)-th light emitting element ED_W2 to (1-4)-th light emitting element ED_W4 might not be reduced by the light blocking layer BM. Accordingly, when the display device DD (see FIG. 6) operates in the first mode, the display device DD may display an image with the first viewing angle wider than the second viewing angle.

In addition, as the size of each of the (2-1)-th transmission hole TH21 and the (2-2)-th transmission hole TH22 is smaller than the size of the sensor opening part SOP, the range (the size or the area) of the image capturing region to be obtained by each of the first and second light receiving elements OPD1 and OPD2 may be reduced. When the range of the image capturing region is reduced, a signal to noise ratio (SNR) of a sensing signal sensed through the first and second light receiving elements OPD1 and OPD2 may be increased. Accordingly, the sensing performance of the sensors FX (see FIG. 6) may be increased.

The second overcoating layer OCL2 may be disposed on the capping layer CPL and the light blocking layer BM. The second overcoating layer OCL2 may be a planarization layer which removes a step difference between the light blocking layer BM and the capping layer CPL. When the capping layer CPL is omitted, the second overcoating layer OCL2 may be a planarization layer which removes a step difference between the light blocking layer BM and the first overcoating layer OCL1.

According to an embodiment of the present disclosure, the first overcoating layer OCL1 may have a thickness that is greater a thickness of the second overcoating layer OCL2. The first overcoating layer OCL1 may be a layer for determining the distance between the light blocking layer BM and the first and second light receiving elements OPD1 and OPD2. For example, the range (the size or the area) of the image capturing region may be determined based on the thickness of the first overcoating layer OCL1 and the size of each of the (2-1)-th and the (2-2)-th transmission holes TH21 and TH22 disposed in the light blocking layer BM. The thickness of the first overcoating layer OCL1 and the size of each of the (2-1)-th and the (2-2)-th transmission holes TH21 and TH22 may be set such that the image capturing region has a desired range.

The window assembly WM may be disposed on the second overcoating layer OCL2. When the thickness of the window assembly WM is increased, the range of the image capturing region may be increased. Accordingly, when the thickness of the window assembly WM is increased, the sizes of the (2-1)-th transmission hole TH21 and the (2-2)-th transmission hole TH22 may be reduced to prevent the range of the image capturing region from being increased.

The light blocking filter BCF illustrated in FIGS. 9A and 9B may be disposed therein with a first filter hole CFH1 having a first size (or a first width) corresponding to the first and second light receiving elements OPD1 and OPD2. The first filter hole CFH1 may have a size greater than the sizes of the (2-1)-th transmission hole TH21 and the (2-2)-th transmission hole TH22.

Referring to FIG. 9C, the light blocking layer BM (see FIG. 9A) may be removed from regions corresponding to or adjacent to the (1-1)-th light emitting element ED_W1 to the (1-4)-th light emitting element ED_W4, and may be removed from regions corresponding to and adjacent to the first and second light receiving elements OPD1 and OPD2. In this case, the range of the image capturing region of the first and second light receiving elements OPD1 and OPD2 may be controlled by a light blocking filter BCFa.

The light blocking filter BCFa may be disposed therein with a second filter hole CFH2 having a second size (or a second width) W2 corresponding to the first and second light receiving elements OPD1 and OPD2. The second size W2 of the second filter hole CFH2 may be smaller than the first size (or the first width) W1 of the first filter hole CFH1 illustrated in FIG. 9B. As the size of the second filter hole CFH2 is reduced, the size of the dummy color filter DCFa illustrated in FIG. 9C may be smaller than the size of the dummy color filter DCF illustrated in FIG. 9B. In FIG. 9C, the second filter hole CFH2 disposed in the light blocking filter BCFa may function as the (2-1)-th transmission hole TH21 and the (2-2)-th transmission hole TH22 to control the range of the image capturing region in FIGS. 9A and 9B. Accordingly, the second filter hole CFH2 disposed in the light blocking filter BCFa may be referred to as a second transmission hole of the optical path control layer OSL.

Thus, the multilayer structure of a display device may include pixel driving circuits, light-emitting elements, light-receiving sensors, and a complex stack of insulating, conductive, and filtering layers. Each pixel may include an anode, emission layer, and common cathode, while the sensors use similar structures with light-receiving layers made from organic materials. A light-blocking layer with carefully sized transmission holes is used to limit viewing angles in privacy mode and enhance sensor signal accuracy by controlling the light capture area, with overcoating and filtering layers further fine-tuning the optical and physical properties of the display for both image rendering and sensing performance.

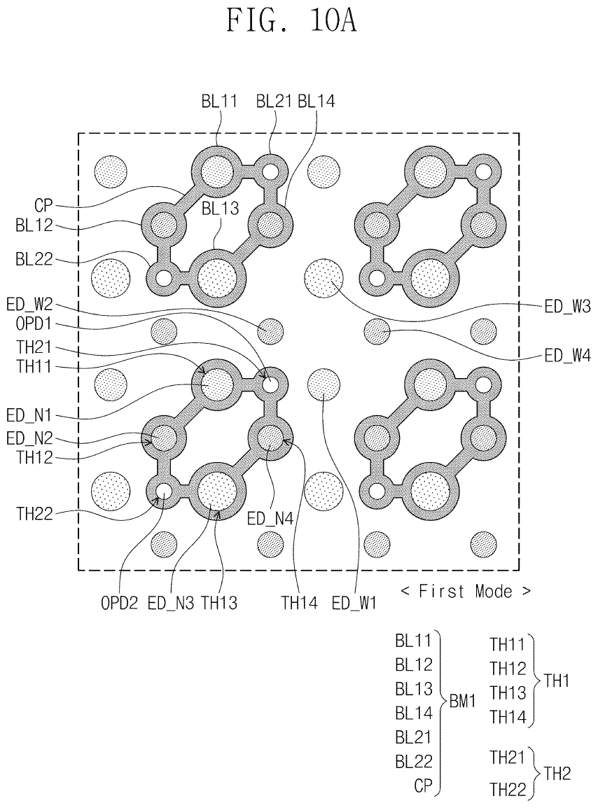

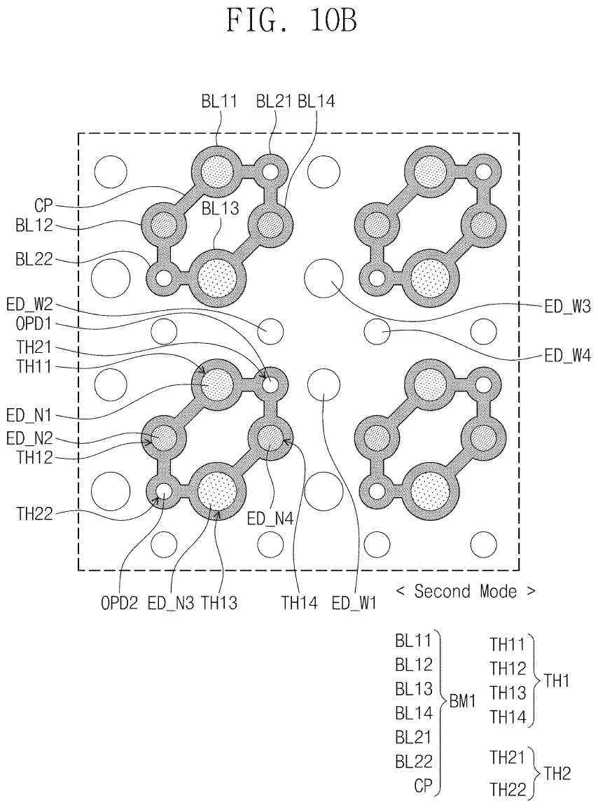

FIG. 10A is a plan view illustrating a display panel operating in a first mode, according to an embodiment of the present disclosure. FIG. 10B is a plan view illustrating a display panel operating in a second mode, according to an embodiment of the present disclosure.

Referring to FIGS. 10A and 10B, the plurality of pixels PX_W and PX_N (see FIG. 6) are disposed in the display panel DP. Each of the pixels PX_W and PX_N may include a light emitting element. Some of the pixels PX_W and PX_N may be wide pixels PX_W (or the first-type pixels), and remaining pixels of the pixels PX_W and PX_N may be narrow pixels PX_N (or the second-type pixels). Each of the wide pixels PX_W includes a (1-1)-th pixel, a (1-2)-th pixel, a (1-3)-th pixel, and a (1-4)-th pixel, and each of the narrow pixels PX_N includes a (2-1)-th pixel, a (2-2)-th pixel, a (2-3)-th pixel, and a (2-4)-th pixel.

The (1-1)-th pixel, the (1-2)-th pixel, the (1-3)-th pixel, and the (1-4)-th pixel include the (1-1)-th light emitting element ED_W1, the (1-2)-th light emitting element ED_W2, the (1-3)-th light emitting element ED_W3, and the (1-4)-th light emitting element ED_W4, respectively. The (2-1)-th pixel, the (2-2)-th pixel, the (2-3)-th pixel, and the (2-4)-th pixel include the (2-1)-th light emitting element ED_N1, the (2-2)-th light emitting element ED_N2, the (2-3)-th light emitting element ED_N3, and the (2-4)-th light emitting element ED_N4, respectively. Each of the (1-1)-th light emitting element ED_W1 to the (1-4)-th light emitting element ED_W4 and each of the (2-1)-th light emitting element ED_N1 to (2-4)-th light emitting element ED_N4 may have a circular shape. However, the embodiment of the present disclosure are not necessarily limited thereto.

The (1-1)-th, (1-2)-th, (1-3)-th, and (1-4)-th pixels may constitute one wide pixel unit (hereinafter, referred to as a “first pixel unit”), and the (2-1)-th, (2-2)-th, (2-3)-th, and (2-4)-th pixels may constitute one narrow pixel unit (hereinafter, referred to as a “second pixel unit”).

The plurality of sensors FX (see FIG. 6) may include a first sensor and a second sensor. The first sensor includes the first light receiving element OPD1, and the second sensor includes the second light receiving element OPD2. The first light receiving element OPD1 may be disposed adjacent to one side of the (1-1)-th light emitting element ED_W1, the (1-2)-th light emitting element ED_W2, the (1-3)-th light emitting element ED_W3, and the (1-4)-th light emitting element ED_W4, and the second light receiving element OPD2 may be disposed adjacent to one side of the (2-1)-th light emitting element ED_N1, the (2-2)-th light emitting element ED_N2, the (2-3)-th light emitting element ED_N3, and the (2-4)-th light emitting element ED_N4. According to an embodiment of the present disclosure, each of the first and second light receiving elements OPD1 and OPD2 may have a circular shape. However, the present disclosure is not necessarily limited thereto.

The display device DD (see FIG. 6) may display an image using the first pixel unit and the second pixel unit in the first mode. In the second mode, the first pixel unit is turned off, so the display device DD may display an image only using the second pixel unit.

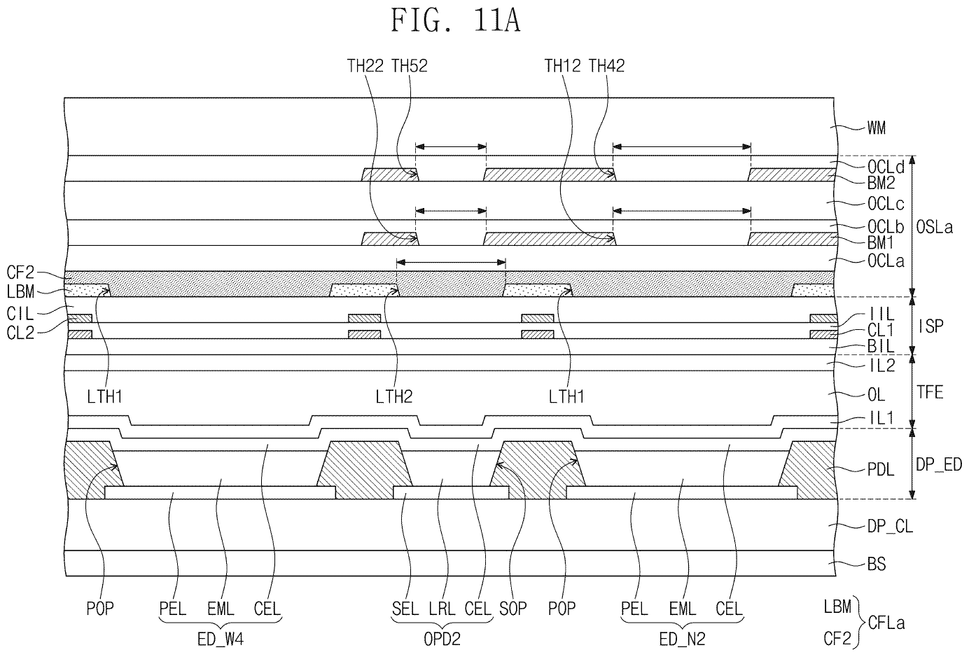

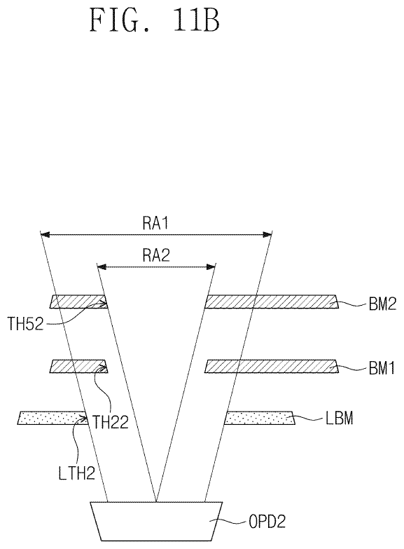

An optical path control layer OSLa (see FIG. 11A) is disposed on the display panel DP. The optical path control layer OSLa may include a first light blocking layer BM1. The first light blocking layer BM1 includes the (1-1)-th to (1-4)-th light blocking rings BL11, BL12, BL13, and BL14 surround the (2-1)-th light emitting element ED_N1, the (2-2)-th light emitting element ED_N2, the (2-3)-th light emitting element ED_N3, and the (2-4)-th light emitting element ED_N4. The first light blocking layer BM1 may further include the (2-1)-th light blocking ring BL21 and the (2-2)-th light blocking ring BL22 surround the first and second light receiving elements OPD1 and OPD2, respectively. For example, the (1-1)-th to (1-4)-th light blocking rings BL11, BL12, BL13, and BL14, and the (2-1)-th light blocking ring BL21 and the (2-2)-th light blocking ring BL22 are connected to each other through a connecting unit CP, to have an integral shape, e.g., a shape that is singular, continuous, and uninterrupted.

The first light blocking layer BM1 may include the first transmission hole TH1, which corresponds to the light emitting elements ED_N1 to ED_N4 of the second pixel unit, and the second transmission hole TH2 which corresponds to the light receiving elements OPD1 and OPD2. The first transmission hole TH1 includes the (1-1)-th transmission hole TH11, the (1-2)-th transmission hole TH12, the (1-3)-th transmission hole TH13, and the (1-4)-th transmission hole TH14 corresponding to the (2-1)-th light emitting element ED_N1, the (2-2)-th light emitting element ED_N2, the (2-3)-th light emitting element ED_N3, and the (2-4)-th light emitting element ED_N4. The second transmission hole TH2 may further include the (2-1)-th transmission hole TH21 and the (2-2)-th transmission hole TH22 corresponding to the first and second light receiving elements OPD1 and OPD2, respectively.

The (1-1)-th transmission hole TH11 to the (1-4)-th transmission hole TH14 are disposed in the (1-1)-th to (1-4)-th light blocking rings BL11, BL12, BL13, and BL14, respectively, and the (2-1)-th transmission hole TH21 and the (2-2)-th transmission hole TH22 are disposed in the (2-1)-th light blocking ring BL21 and the (2-2)-th light blocking ring BL22, respectively. Each of the (1-1)-th to (1-4)-th light blocking rings BL11, BL12, BL13, and BL14 may control a viewing angle of light emitted from a relevant one of the (2-1)-th light emitting element ED_N1 to (2-4)-th light emitting element ED_N4, respectively. The (2-1)-th light blocking ring BL21 and the (2-2)-th light blocking ring BL22 may control the range (size or area) of an image (or fingerprint) capturing region obtained by the first and second light receiving elements OPD1 and OPD2.

Thus, the display panel may operate in two modes using two types of pixel units: wide (first-type) pixel unit and narrow (second-type) pixel unit, each comprising four sub-pixels with circular light-emitting elements and adjacent optical sensors. In the first mode, both pixel types are active for a wide viewing angle, while in the second mode, only the narrow pixel units are used, and a light-blocking layer with integrated transmission holes selectively limits the light output and sensor capture range to enable privacy viewing and improve sensing accuracy.

FIG. 11A is a cross-sectional view illustrating a (1-4)-th light emitting element, a (2-2)-th light emitting element, and a second light receiving element according to an embodiment of the present disclosure. FIG. 11B is a view illustrating the range of an image capturing region adjusted by the first and second light blocking layer illustrated in FIG. 11A. Components, which are the same as the components illustrated in FIGS. 9A and 9B, from among components illustrated in FIG. 11A will be assigned with the same reference numerals, and to the extent that an element is not described in detail with respect to this figure, it may be understood that the element is at least similar to a corresponding element that has been described elsewhere within the present disclosure.

Referring to FIG. 11A, the element layer DP_ED is disposed on the circuit layer DP_CL. The element layer DP_ED may include the (1-1)-th to (1-4)-th elements ED_W1 to ED_W4, the (2-1)-th to (2-4)-th light emitting elements ED_N1 to ED_N4, and the first and second light receiving elements OPD1 and OPD2. FIG. 11A illustrates the (1-4)-th light emitting element ED_W4 and the (2-2)-th light emitting element ED_N2, and the second light receiving element OPD2. Other light emitting elements not illustrated in FIG. 11A have similar cross-sectional structures, and to the extent that an element is not described in detail with respect to this figure, it may be understood that the element is at least similar to a corresponding element that has been described elsewhere within the present disclosure.

The element layer DP_ED is covered by the encapsulating layer TFE. The input sensing layer ISP is disposed over the encapsulating layer TFE, and the optical path control layer OSLa is disposed on the input sensing layer ISP. The optical path control layer OSLa may include a color filter layer CFLa, a first overcoating layer OCLa, the first light blocking layer BM1, a second overcoating layer OCLb, a third overcoating layer OCLc, a second light blocking layer BM2, and a fourth overcoating layer OCLd.

The color filter layer CFLa includes first to third color filters and a lower light blocking layer LBM. FIG. 11A illustrates only the second color filter CF2, which corresponds to the (1-4)-th light emitting element ED_W4, the second light receiving element OPD2, and the (2-2)-th light emitting element ED_N2, among the first to third color filters. The lower light blocking layer LBM overlaps the color filters in the non-emission region. According to an embodiment of the present disclosure, the lower light blocking layer LBM may be formed in an entire portion of the non-emission region. The lower light blocking layer LBM may overlap the pixel defining layer PDL, in a plan view. The lower light blocking layer LBM may be disposed therein with first and second lower transmission holes LTH1 and LTH2 to correspond to the pixel opening part POP and the sensor opening part SOP. The first and second lower transmission holes LTH1 and LTH2 may have sizes corresponding to (or substantially the same as) the sizes of the pixel opening part POP and the sensor opening part SOP, respectively.

The first overcoating layer OCLa may be disposed on the color filter layer CFLa. The first overcoating layer OCLa may be a planarization layer which covers over a step difference between the color filters and the lower light blocking layer LBM.

The first light blocking layer BM1 is disposed on the first overcoating layer OCLa. The first light blocking layer BM1 may surround the light receiving region of the second light receiving element OPD2 and the emission region of the (2-2)-th light emitting element ED_N2. The first light blocking layer BM1 may absorb or block ambient light incident thereto. The first light blocking layer BM1 may include an organic light blocking material. For example, the organic light blocking material may include one of carbon black and titan black, but the present disclosure is not necessarily limited thereto. The first light blocking layer BM1 may overlap a lower light blocking layer LBM in a plan view. While the lower light blocking layer LBM is formed in the entire portion of the non-emission region, the first light blocking layer BM1 is disposed at a position, which is for surrounding the emission regions of the (2-1)-th to (2-4)-th light emitting elements ED_N1 to ED_N4, and the light receiving region of the first and second light receiving elements OPD1 and OPD2, in the non-emission region. For example, the first light blocking layer BM1 might not be disposed in a region, which is adjacent to the (1-1)-th to (1-4)-th light emitting elements ED_W1 to ED_W4, in the non-emission region.

The first light blocking layer BM1 may be disposed therein with the plurality of first transmission holes TH1 (see FIG. 10A) and the plurality of second transmission holes TH2 (see FIG. 10A). FIG. 11A illustrates the (1-2)-th transmission hole TH12, which corresponds to the (2-2)-th light emitting element ED_N2, of the plurality of first transmission holes TH1, and the (2-2)-th transmission hole TH22, which corresponds to the second light receiving element OPD2, of the plurality of second transmission holes TH2. According to an embodiment of the present disclosure, the (1-2)-th transmission hole TH12 has a size that is smaller than the size of the first lower transmission hole LTH1, and the (2-2)-th transmission hole TH22 has a size that is smaller than the size of the second lower transmission hole LTH2.

The second overcoating layer OCLb may be disposed on the first light blocking layer BM1 and the first overcoating layer OCLa. The second overcoating layer OCLb may be a planarization layer which covers over a step difference between the first light blocking layer BM1 and the first overcoating layer OCLa. The third overcoating layer OCLc may be disposed on the second overcoating layer OCLb. The third overcoating layer OCLc may be formed in an inkjet manner.

The second light blocking layer BM2 is disposed on the third overcoating layer OCLc. The second light blocking layer BM2 may surround the light receiving region of the second light receiving element OPD2 and the emission region of the (2-2)-th light emitting element ED_N2. According to an embodiment of the present disclosure, the second light blocking layer BM2 may include a material that is the same as the first light blocking layer BM1. The second light blocking layer BM2 is disposed at a position, which is for surrounding the emission regions of the (2-1)-th to (2-4)-th light emitting elements ED_N1 to ED_N4, and the light receiving regions of the first and second light receiving elements OPD1 and OPD2, in the non-emission region. For example, the second light blocking layer BM2 might not be disposed in a region, which is adjacent to the (1-1)-th to (1-4)-th light emitting elements ED_W1 to ED_W4, in the non-emission region.

The second light blocking layer BM2 may be disposed therein with a plurality of fourth transmission holes and a plurality of fifth transmission holes. FIG. 11A illustrates the (4-2)-th transmission hole TH42, which corresponds to the (2-2)-th light emitting element ED_N2, of the plurality of fourth transmission holes, and the (5-2)-th transmission hole TH52, which corresponds to the second light receiving element OPD2, of the plurality of fifth transmission holes. According to an embodiment of the present disclosure, the (4-2)-th transmission hole has a size smaller than or equal to the size of the (1-2)-th transmission hole TH12, and the (5-2)-th transmission hole TH52 has a size smaller than or equal to the size of the (2-2)-th transmission hole TH22.

As the sizes of each of the (1-2)-th transmission hole TH12 and a (4-2)-th transmission hole TH42 is formed to be smaller than the size of the pixel opening part POP, the range of the viewing angle of light output from the (2-2)-th light emitting element ED_N2 may be reduced by the first and second light blocking layers BM1 and BM2. Accordingly, when the display device DD (see FIG. 6) operates in the second mode, the display device DD may display an image with the second viewing angle that is narrower than the first viewing angle.

As illustrated in FIG. 11B, as the size of each of the (2-2)-th transmission hole TH22 and the (5-2)-th transmission hole TH52 is reduced to be smaller than the size of the sensor opening part SOP and the size of the second lower transmission hole LTH2 of the lower light blocking layer LBM, the range (the size or the area) of the image capturing region to be obtained by the second light receiving element OPD2 may be reduced. When the optical system (e.g., a transmission hole) is not formed on the second light receiving element OPD2 by using the first and second light blocking layers BM1 and BM2, the image capturing region may be set to the first range RA1. However, the optical system may be formed on the second light receiving element OPD2 by using the (2-2)-th transmission hole TH22 and the (5-2)-th transmission hole TH52 formed in the first and second light blocking layers BM1 and BM2. In this case, the range of the image capturing region may be set to the second range RA2 smaller than the first range RA1. As the range of the image capturing region is decreased, a signal-to-noise ratio of the sensing signal sensed through the second light receiving element OPD2 may be increased. Accordingly, the sensing performance of the sensors FX (see FIG. 6) may be increased.

Referring back to FIG. 11A, the fourth overcoating layer OCLd may be disposed on the third overcoating layer OCLc and the second light blocking layer BM2. The fourth overcoating layer OCLd may be a planarization layer which removes a step difference between the second light blocking layer BM2 and the third overcoating layer OCLc.

The third overcoating layer OCLc may have a thickness that is greater than thicknesses of the second and fourth over-coating layers OCLb and OCLd. The third overcoating layer OCLc may be a layer for determining the distance between the second light blocking layer BM2 and the second light receiving element OPD2. For example, the range (the size or the area) of the image capturing region may be determined based on the thickness of the third overcoating layer OCLc and the size of each of the (2-2)-th and the (5-2)-th transmission holes TH22 and TH52 disposed in the first and second light blocking layers BM1 and BM2. The thickness of the third overcoating layer OCLc and the size of each of the (2-2)-th and the (5-2)-th transmission holes TH22 and TH52 may be set such that the image capturing region has a desired range.

The window assembly WM may be disposed on the fourth overcoating layer OCLd. When the thickness of the window assembly WM is increased, the range of the image capturing region may be increased. Accordingly, when the thickness of the window assembly WM is increased, the sizes of the (2-2)-th transmission hole TH22 and the (5-2)-th transmission hole TH52 may be reduced to prevent the range of the image capturing region from being increased.

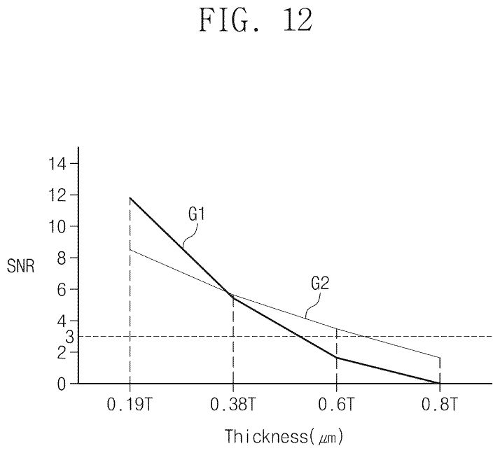

FIG. 12 is a graph illustrating a signal-to-noise ratio as a function of a thickness of the window. A first graph G1 represents the signal-to-noise ratio measured in a product according to a comparative example, and a second graph G2 represents a signal-to-noise ratio measured in a product according to the present disclosure.

Referring to FIG. 12, as the thickness of the window assembly WM (see FIG. 11A) is increased, the range (size or area) of the image capturing region is increased. Accordingly, the signal-to-noise ratio of a sensing signal sensed by the first and second light receiving elements OPD1 and OPD2 may be increased.

However, when a hole is formed in the light blocking layer BM and/or the light blocking filter BCF and used as an optical system as illustrated in FIGS. 9A to 9C, or when a hole is formed in the first and second light blocking layers BM1 and BM2 as illustrated in FIG. 11A and used as an optical system, the signal-to-noise ratio may be prevented from being increased. For example, the structure according to the present disclosure shows a signal-to-noise ratio maintained to at least 3, even if the thickness of the window assembly WM is increased to 0.6 μm. However, when a transmission hole is formed in the light blocking layer BM and/or the light blocking filter BCF and used as an optical system as illustrated in FIGS. 9A to 9C, or when a transmission hole is formed in the first and second light blocking layers BM1 and BM2 and used as an optical system as illustrated in FIG. 11A, the sensing performance of the sensor FX (see FIG. 6) may be prevented from being degraded, even if the thickness of the window assembly WM is increased.

The display device, according to an embodiment, may be applicable to various electronic devices. An example of an electronic device, according to an embodiment, includes the display device described above, and may further include a module or a device having other additional functions, in addition to the display device.

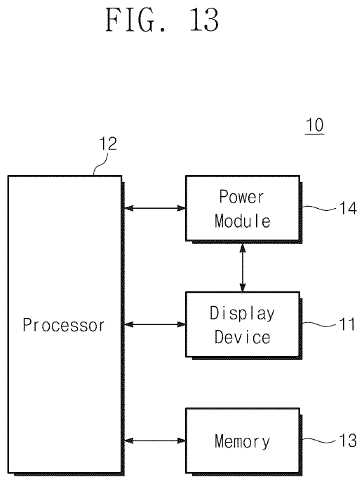

FIG. 13 is a block diagram of an electronic apparatus according to an embodiment.

Referring to FIG. 13, an electronic apparatus 10, according to an embodiment, may include a display device 11, a processor 12, a memory 13, and a power module 14.

The processor 12 may include at least one a central processing unit (CPU), an application processor (AP), a graphic processing unit (GPU), a communication processor (CP), an image signal processor (ISP), or a controller.

The memory 13 may store data information necessary for the operation of the processor 12 or the display device 11. When the processor 12 runs the application stored in the memory 13, an image data signal and/or an input control signal may be transmitted to the display device 11, and the display device 11 may process the received signal and output the image information through the display screen.

The power module 14 may include a power supply module, such as a power adaptor or a battery device, and a power converting module to convert the power supplied from the power supply module into power necessary for the operation of the electronic apparatus 10.

At least one of components of the electronic apparatus 10 described above may be included in the display device 11, according to embodiments described above. In addition, some of individual modules functionally included in one module may be included in the display device 11, and others of the individual modules may be provided separately from the display device 11. For example, the processor 12, the memory 13, and the power module 14 may be provided in the form of another device in the electronic apparatus 10, instead of the display device 11.

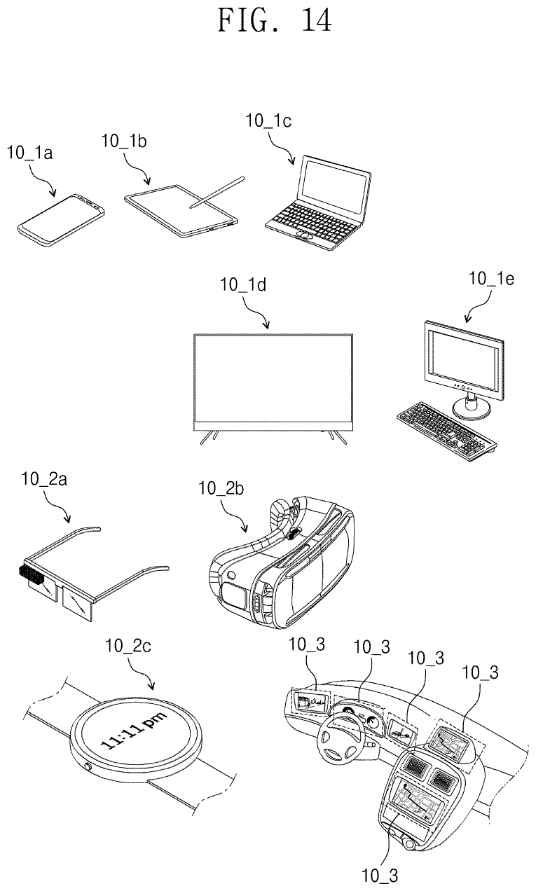

FIG. 14 is a schematic view illustrating electronic apparatuses according to various embodiments.

Referring to FIG. 14, various electronic apparatuses employing the display device according to embodiments may include a wearable electronic apparatus including a display module such as smart glasses 10_2a, a head mounted display 10_2b, and a smart watch 10_2c, and an electronic apparatus 10-3 for the vehicle including the display module such as a center information display (CID), which is disposed in an instrument panel, a center facia, and a dashboard of a vehicle, or a room mirror display, as well as an electronic apparatus for image display such as a smartphone 10_1a, a tablet computer 10_1b, a laptop/notebook computer 10_1c, a television (TV) 10_1d, and a computer monitor 10_1e.

According to the present disclosure, the display device may include the optical path control layer disposed on the display panel to control the viewing angle of the second-type pixel, and the transmission hole may be formed in the optical path control layer to correspond to the light receiving element. The size of the transmission hole may be adjusted to control the range of an image capturing region to be obtained by the light receiving element. Accordingly, as the image capturing region is increased, the sensing performance of the sensor might not be lowered.

Although an embodiment of the present disclosure has been described for illustrative purposes, those skilled in the art will appreciate that various modifications, and substitutions are possible, without departing from the scope and spirit of the present disclosure as disclosed in the accompanying claims.

While the present disclosure has been described with reference to embodiments thereof, it will be apparent to those of ordinary skill in the art that various changes and modifications may be made thereto without departing from the spirit and scope of the present disclosure.

What is claimed is:

1. A display device, comprising:
a display panel including a first-type pixel, a second-type pixel, and a sensor, the display panel configured to display an image using the first-type pixel and the second-type pixel in a first mode, and to display an image using the second-type pixel and not using the first-type pixel in a second mode;
an optical path control layer disposed on the display panel; and
a panel driver configured to drive the display panel in the first mode or the second mode,
wherein the display panel includes:
a base layer;
a circuit layer disposed on the base layer; and
an element layer disposed on the circuit layer, and including a first light emitting element of the first-type pixel, a second light emitting element of the second-type pixel, and a light receiving element of the sensor, and
wherein the optical path control layer is disposed on the element layer, and includes a first transmission hole corresponding to the second light emitting element, and a second transmission hole corresponding to the light receiving element.

2. The display device of claim 1, wherein the optical path control layer includes:
a first overcoating layer;
a light blocking layer disposed on the first overcoating layer; and
a second overcoating layer disposed on the light blocking layer,
wherein the first transmission hole and the second transmission hole are disposed in the light blocking layer.

3. The display device of claim 2, wherein the optical path control layer further includes:
a color filter layer disposed under the first overcoating layer,
wherein the color filter layer includes:
color filters corresponding to emission regions defined by the first light emitting element and the second light emitting element; and
a dummy color filter corresponding to a sensing region defined by the light receiving element.

4. The display device of claim 3, wherein the color filter layer further includes:
a light blocking filter corresponding to a non-emission region which is in a non-overlap state with the first light emitting element, the second light emitting element, and the light receiving element,
wherein the light blocking filter has a structure in which at least two color filters having mutually different colors are stacked.

5. The display device of claim 2, wherein the light blocking layer has ring shape, in a non-emission region and surrounds an emission region defined by the second light emitting element, and a sensing region defined by the light receiving element, in a plan view.

6. The display device of claim 2, wherein the optical path control layer further includes:
a third transmission hole corresponding to the first light emitting element,
wherein a size of the first transmission hole is smaller than a size of the third transmission hole.

7. The display device of claim 6, wherein the third transmission hole is disposed in the light blocking layer.

8. The display device of claim 2, wherein the first overcoating layer has a thickness that is greater than a thickness of the second overcoating layer.

9. The display device of claim 1, wherein the optical path control layer further includes:
a color filter layer including a light blocking filter;
a first overcoating layer disposed on the color filter layer;
a light blocking layer disposed on the first overcoating layer; and
a second overcoating layer disposed on the light blocking layer,
wherein the first transmission hole is disposed in the light blocking layer, and
wherein the second transmission hole is disposed in the light blocking filter.

10. The display device of claim 9, wherein the color filter layer further includes:
color filters corresponding to emission regions defined by the first light emitting element and the second light emitting element; and
a dummy color filter corresponding to a sensing region defined by the light receiving element, and
wherein the light blocking filter corresponds to a non-emission region which is a non-overlap state with the first and second light emitting elements and the light receiving element, and has a structure in which at least two color filters having mutually different colors are stacked.

11. The display device of claim 1, wherein the optical path control layer further includes:
a first overcoating layer;
a first light blocking layer disposed on the first overcoating layer;
a second overcoating layer disposed on the first light blocking layer; and
a second light blocking layer disposed on the second overcoating layer,
wherein the first and second transmission holes are disposed in at least one of the first and second light blocking layers.

12. The display device of claim 11, wherein the optical path control layer further includes:
a color filter layer disposed under the first overcoating layer,
wherein the color filter layer includes:
color filters corresponding to emission regions defined by the first light emitting element and the second light emitting element; and
a dummy color filter corresponding to a sensing region defined by the light receiving element.

13. The display device of claim 12, wherein the color filter layer further includes:
a lower light blocking layer interposed between the color filters and the dummy color filter,
wherein the lower light blocking layer includes:
a first lower transmission hole corresponding to the second light emitting element; and
a second lower transmission hole corresponding to the light receiving element.

14. The display device of claim 13, wherein a size of the first transmission hole is smaller than a size of the first lower transmission hole.

15. The display device of claim 13, wherein a size of the second transmission hole is smaller than a size of the second lower transmission hole.

16. The display device of claim 11, wherein the optical path control layer further includes:
a third overcoating layer interposed between the second overcoating layer and the second light blocking layer,
wherein the third overcoating layer has a thickness that is greater than a thickness of the second overcoating layer.

17. The display device of claim 11, wherein the optical path control layer further includes:
a fourth overcoating layer covering the second light blocking layer.

18. The display device of claim 1, wherein the element layer further includes:
a pixel defining layer disposed among the first light emitting element, the second light emitting element, and the light receiving element,
wherein the pixel defining layer includes a light absorbing material.

19. The display device of claim 1, wherein the display panel further includes:
an encapsulating layer disposed on the element layer; and
an input sensing layer disposed between the encapsulating layer and the optical path control layer.

20. An electronic device, comprising:
a display panel including a first-type pixel, a second-type pixel, and a sensor, and configured to display an image using the first-type pixel and the second-type pixel in a first mode, and to display an image using the second-type pixel and not the first-type pixel in a second mode;
an optical path control layer disposed on the display panel;
a panel driver configured to drive the display panel in the first mode or the second mode; and
a processor configured to provide an image signal to the panel driver,
wherein the display panel includes:
a base layer;
a circuit layer disposed on the base layer; and
an element layer disposed on the circuit layer, and including a first light emitting element of the first-type pixel, a second light emitting element of the second-type pixel, and a light receiving element of the sensor,
wherein the optical path control layer is disposed on the element layer, and includes a first transmission hole corresponding to the second light emitting element, and a second transmission hole corresponding to the light receiving element.
